(19) United States
(12) Patent Application Publication
(10) Pub. No.: US 2024/0420764 A1
(43) Pub. Date: Dec. 19, 2024

(54) MEMORY DEVICE

(71) Applicant: Kioxia Corporation, Tokyo (JP)

(72) Inventor: Hiroshi MAEJIMA, Tokyo (JP)

(73) Assignee: Kioxia Corporation, Tokyo (JP)

(21) Appl. No.: 18/732,967

(22) Filed: Jun. 4, 2024

(30) Foreign Application Priority Data
Jun. 14, 2023 (JP) 2023-098039

(51) Int. Cl. G11C 16/08; H01L 23/00; H01L 25/065; H01L 25/18; H10B 80/00

(52) U.S. Cl. CPC G11C 16/08; H01L 24/08; H01L 25/0657; H01L 25/18; H10B 80/00; H01L 2224/08145; H01L 2924/1431; H01L 2924/14511

(57) ABSTRACT

According to one embodiment, a memory device includes: a first chip including a first memory cell array; a second chip in contact with the first chip and including a second memory cell array; and a third chip in contact with the second chip and including a control circuit. The first memory cell array includes first and second transistors coupled in series. The second memory cell array includes third and fourth transistors coupled in series. The control circuit includes: fifth, sixth, and seventh transistors respectively having first ends coupled to gates of the first, third, and second and fourth transistors; a first decoder configured to switch a state of the fifth transistor; and a second decoder configured to switch a state of the sixth transistor independently of the state of the fifth transistor.

### CROSS-REFERENCE TO RELATED APPLICATIONS

This application is based upon and claims the benefit of priority from Japanese Patent Application No. 2023-098039, filed Jun. 14, 2023, the entire contents of which are incorporated herein by reference.

### FIELD

Embodiments described herein relate generally to a memory device.

### BACKGROUND

A NAND flash memory has been known as a memory device capable of storing data in a nonvolatile manner. In a memory device such as a NAND flash memory, a three-dimensional memory structure is adopted for high integration and large capacity. The three-dimensional memory structure and a CMOS circuit for controlling the memory structure may be provided on separate chips. In this case, the memory device is formed by bonding a memory chip provided with the three-dimensional memory structure and a circuit chip provided with the CMOS circuit.

### BRIEF DESCRIPTION OF DRAWINGS

FIG. 1 is a block diagram illustrating a configuration of a memory system including a memory device according to a first embodiment.

FIG. 2 is a circuit diagram illustrating an example of a configuration of a memory cell array according to the first embodiment.

FIG. 3 is a circuit diagram illustrating an example of connection among the memory cell array, a row decoder module, and a driver module according to the first embodiment.

FIG. 4 is a circuit diagram illustrating an example of a configuration of a first portion of a block decoder according to the first embodiment.

FIG. 5 is a circuit diagram illustrating an example of a configuration of a second portion of the block decoder according to the first embodiment.

FIG. 6 is a circuit diagram illustrating an example of a configuration of a third portion of the block decoder according to the first embodiment.

FIG. 7 is a perspective view illustrating an example of a bonding structure of the memory device according to the first embodiment.

FIG. 8 is a cross-sectional view illustrating an example of a cross-sectional structure of the memory device according to the first embodiment.

FIG. 9 is a cross-sectional view of a region IX in FIG. 8, illustrating an example of a cross-sectional structure of a memory pillar according to the first embodiment.

FIG. 10 is a cross-sectional view taken along line X-X of FIG. 9, illustrating an example of a cross-sectional structure of a memory cell transistor according to the first embodiment.

FIG. 11 is a timing chart illustrating an example of a set operation of partial bad block information in the memory device according to the first embodiment.

FIG. 12 is a timing chart illustrating an example of a block selection operation in the memory device according to the first embodiment.

FIG. 13 is a circuit diagram illustrating an example of a configuration of a memory cell array of a memory device according to a second embodiment.

FIG. 14 is a circuit diagram illustrating an example of connection among the memory cell array, a row decoder module, and a driver module according to the second embodiment.

FIG. 15 is a cross-sectional view illustrating an example of a cross-sectional structure of the memory device according to the second embodiment.

FIG. 16 is a block diagram illustrating an example of a configuration of a memory cell array according to a third embodiment.

FIG. 17 is a circuit diagram illustrating an example of connection among the memory cell array, a row decoder module, and a driver module according to the third embodiment.

FIG. 18 is a circuit diagram illustrating an example of a configuration of a first portion of a block decoder according to the third embodiment.

FIG. 19 is a circuit diagram illustrating an example of a configuration of a second portion of the block decoder according to the third embodiment.

FIG. 20 is a circuit diagram illustrating an example of a configuration of a first portion of a block decoder according to a fourth embodiment.

FIG. 21 is a circuit diagram illustrating an example of a configuration of a second portion of the block decoder according to the fourth embodiment.

FIG. 22 is a circuit diagram illustrating a first example of a configuration of a first portion of a bad block information storage circuit according to the fourth embodiment.

FIG. 23 is a circuit diagram illustrating a first example of a configuration of a second portion of the bad block information storage circuit according to the fourth embodiment.

FIG. 24 is a circuit diagram illustrating a second example of the configuration of the first portion of the bad block information storage circuit according to the fourth embodiment.

FIG. 25 is a circuit diagram illustrating a second example of the configuration of the second portion of the bad block information storage circuit according to the fourth embodiment.

### DETAILED DESCRIPTION

In general, according to one embodiment, a memory device includes a first chip including a first memory cell array, a second chip including a second memory cell array and in contact with the first chip, and a third chip including a control circuit and in contact with the second chip. The first memory cell array includes a first transistor and a second transistor coupled in series. The second memory cell array includes a third transistor and a fourth transistor coupled in series. The control circuit includes a fifth transistor having a first end electrically coupled to a gate of the first transistor, a sixth transistor having a first end electrically coupled to a gate of the third transistor, a seventh transistor having a first end electrically coupled to a gate of the second transistor and a gate of the fourth transistor, a first decoder configured to switch a state of the fifth transistor, and a second decoder configured to switch a state of the sixth transistor independently of the state of the fifth transistor.

Hereinafter, embodiments will be described with reference to the drawings. Dimensions and ratios of the drawings are not necessarily the same as actual ones.

Note that, in the following description, components having substantially the same functions and configurations are denoted by the same reference numerals. In a case where elements having similar configurations are particularly distinguished from each other, different characters or numbers may be added to the end of the same reference numeral.

Furthermore, in the present specification, in a case where there is a reference sign Xn with “n” at the end of the reference sign X, a voltage level different from the voltage level applied to a configuration corresponding to the reference sign X is applied to a configuration corresponding to the reference sign Xn.

In addition, in the present specification, the “node” may be read as “wiring”. The “logic level of the node” may be read as a “logic level of a signal supplied to the wiring”.

### 1. First Embodiment

A first embodiment will be described.

### 1.1 Configuration

A configuration according to the first embodiment will be described.

### 1.1.1 Memory System

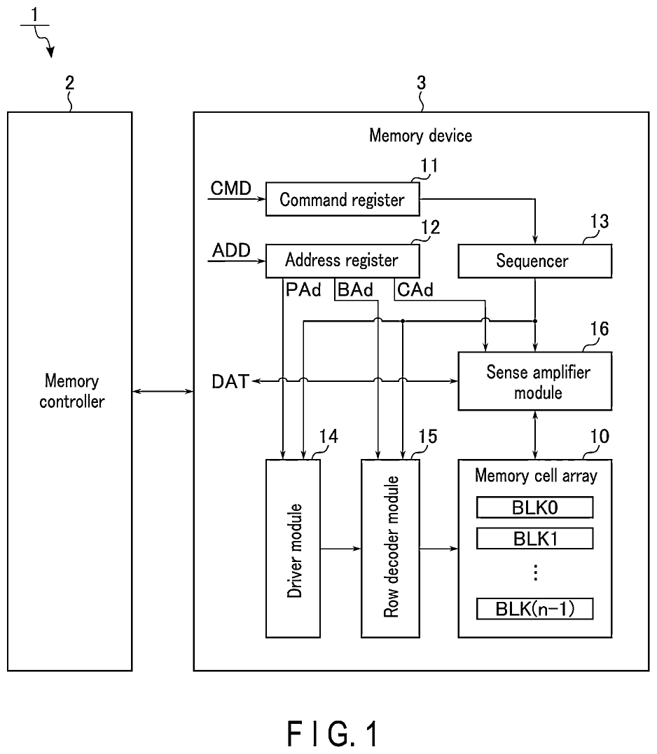

FIG. 1 is a block diagram illustrating an example of a configuration of a memory system including a memory device according to a first embodiment. A memory system 1 is a storage device configured to be connected to an external host (not illustrated). The memory system 1 is, for example, a memory card such as an SD™ card, a universal flash storage (UFS), or a solid state drive (SSD). The memory system 1 includes a memory controller 2 and a memory device 3.

The memory controller 2 includes, for example, an integrated circuit such as a system-on-a-chip (SoC). The memory controller 2 controls the memory device 3 based on a request from the host. Specifically, for example, the memory controller 2 writes data requested to be written by the host to the memory device 3. In addition, the memory controller 2 reads data requested to be read from the host from the memory device 3 and transmits the data to the host.

The memory device 3 is a nonvolatile memory. The memory device 3 is, for example, a NAND flash memory. The memory device 3 stores data in a nonvolatile manner.

Communication between the memory controller 2 and the memory device 3 conforms to, for example, a single data rate (SDR) interface, a toggle double data rate (DDR) interface, or an open NAND flash interface (ONFI).

### 1.1.2 Memory Device

Subsequently, an internal configuration of the memory device according to the first embodiment will be described with reference to the block diagram illustrated in FIG. 1. The memory device 3 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLK (n−1) (n is an integer of 2 or more). The number of blocks BLK included in the memory cell array 10 may be one. The block BLK is an aggregate of a plurality of memory cells. The block BLK is used, for example, as a unit of erasing data. A plurality of bit lines and a plurality of word lines are provided in the memory cell array 10. Each memory cell is associated with, for example, one bit line and one word line. A detailed configuration of the memory cell array 10 will be described later.

The command register 11 stores a command CMD received by the memory device 3 from the memory controller 2. The command CMD includes, for example, a command for causing the sequencer 13 to execute various operations including a read operation, a write operation, an erase operation, and the like.

The address register 12 stores address information ADD received by the memory device 3 from the memory controller 2. The address information ADD includes, for example, a block address BAd, a page address PAd, and a column address CAd. For example, the block address BAd, the page address PAd, and the column address CAd are used to select the block BLK, the word line, and the bit line, respectively.

The sequencer 13 controls the entire operation of the memory device 3. For example, the sequencer 13 controls the driver module 14, the row decoder module 15, the sense amplifier module 16, and the like based on the command CMD stored in the command register 11 to execute a read operation, a write operation, an erase operation, and the like.

The driver module 14 generates a voltage used in a read operation, a write operation, an erase operation, and the like. Then, the driver module 14 applies the generated voltage to the signal line corresponding to the selected word line based on, for example, the page address PAd stored in the address register 12.

The row decoder module 15 selects one corresponding block BLK in the memory cell array 10 based on the block address BAd stored in the address register 12. Then, the row decoder module 15 transfers, for example, the voltage applied to the signal line corresponding to the selected word line to the selected word line in the selected block BLK.

In the write operation, the sense amplifier module 16 applies a desired voltage to each bit line according to write data DAT received from the memory controller 2. In addition, in the read operation, the sense amplifier module 16 determines the data stored in the memory cell based on a voltage of the bit line, and transfers the determination result to the memory controller 2 as read data DAT.

### 1.1.3 Memory Cell Array

Next, a configuration of the memory cell array according to the first embodiment will be described.

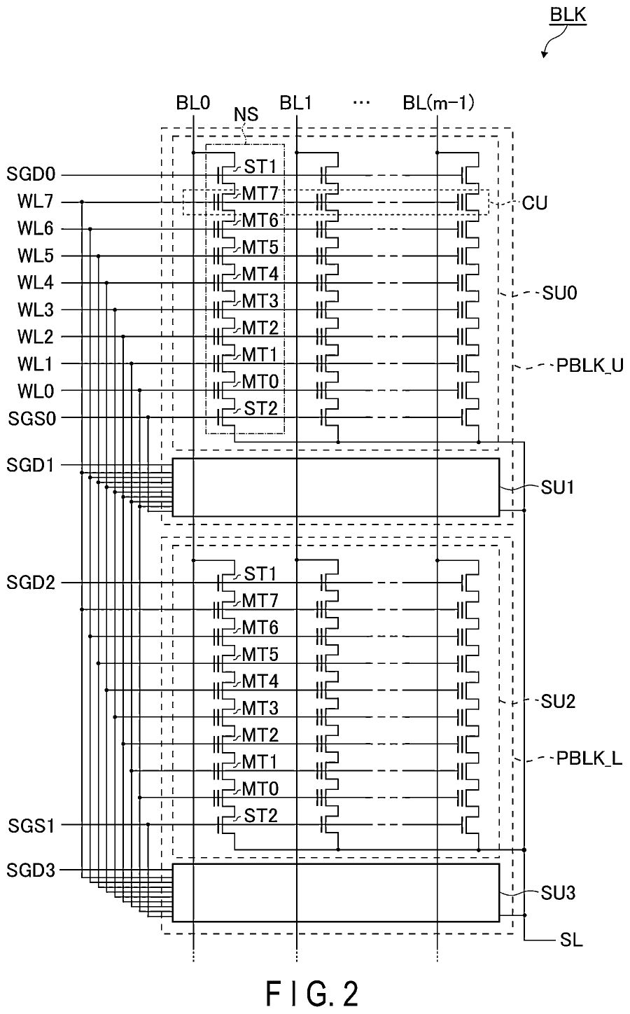

FIG. 2 is a circuit diagram illustrating an example of a circuit configuration of the memory cell array according to the first embodiment. FIG. 2 illustrates one block BLK among the plurality of blocks BLK included in the memory cell array 10. As illustrated in FIG. 2, the block BLK includes, for example, two partial blocks PBLK_U and PBLK_L. The partial block PBLK_U includes, for example, two string units SU0 and SU1. The partial block PBLK_L includes, for example, two string units SU2 and SU3. That is, the block BLK includes, for example, four string units SU0 to SU3.

Each of the string units SU0 to SU3 includes a plurality of NAND strings NS respectively associated with bit lines BL0 to BL (m−1) (m is an integer of 2 or more). The number of the bit lines BL may be one. Each NAND string NS includes, for example, memory cell transistors MT0 to MT7 and select transistors ST1 and ST2. Each memory cell transistor MT includes a control gate and a charge storage film, and stores data in a nonvolatile manner. Each of the select transistors ST1 and ST2 is used to select the string unit SU during various operations.

In each NAND string NS, the memory cell transistors MT0 to MT7 are connected in series. A drain of the select transistor ST1 is connected to the associated bit line BL. A source of the select transistor ST1 is connected to one ends of the memory cell transistors MT0 to MT7 connected in series. A drain of the select transistor ST2 is connected to the other ends of the memory cell transistors MT0 to MT7 connected in series. A source of the select transistor ST2 is coupled to a source line SL.

In the same block BLK, control gates of the memory cell transistors MT0 to MT7 are connected to word lines WL0 to WL7, respectively. Gates of the select transistors ST1 in the string units SU0 to SU3 are connected to select gate lines SGD0 to SGD3, respectively. Gates of the select transistors ST2 in the string units SU0 and SU1 are connected to a select gate line SGS0. Gates of the select transistors ST2 in the string units SU2 and SU3 are connected to a select gate line SGS1.

Different column addresses are allocated to the bit lines BL0 to BL (m−1). Each bit line BL is shared by the NAND string NS to which the same column address is allocated among the plurality of blocks BLK. Each of the word lines WL0 to WL7 is provided for each block BLK. The source line SL is shared among the plurality of blocks BLK, for example.

An aggregate of the plurality of memory cell transistors MT connected to the common word line WL in one string unit SU is referred to as, for example, a cell unit CU. For example, a storage capacity of the cell unit CU including the memory cell transistors MT each storing one-bit data is defined as “one-page data”. The cell unit CU may have a storage capacity of two-page data or more according to the number of bits of data stored in the memory cell transistor MT.

Note that a circuit configuration of the memory cell array 10 included in the memory device 3 according to the first embodiment is not limited to the configuration described above. For example, the number of string units SU included in each block BLK can be designed to any number. The number of the memory cell transistors MT and the select transistors ST1 and ST2 included in each NAND string NS can be designed to any number.

### 1.1.4 Low-Decoder Module

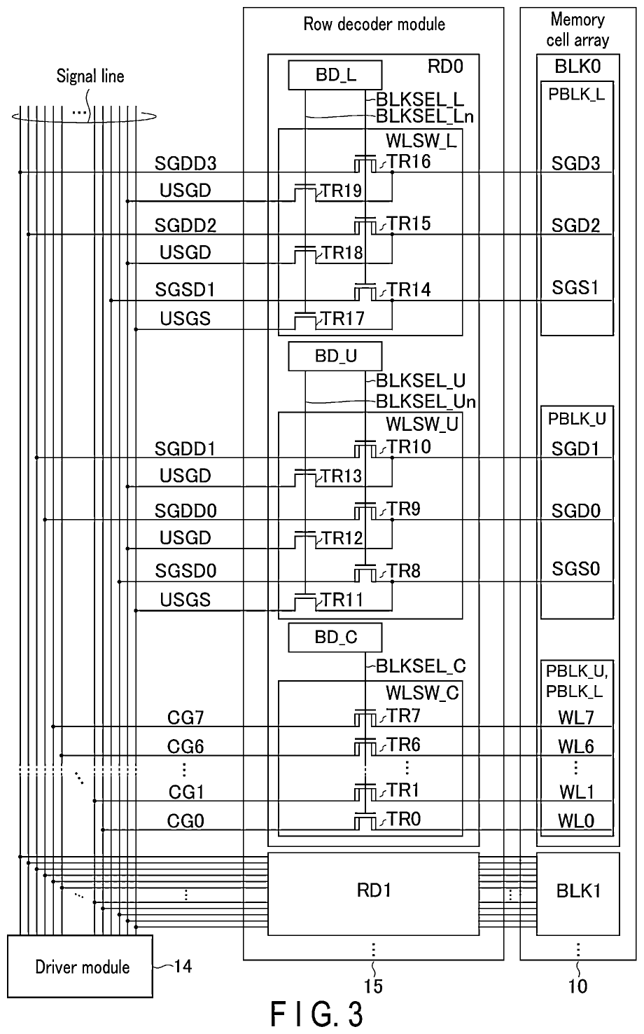

FIG. 3 is a circuit diagram illustrating an example of connection among the memory cell array, the row decoder module, and the driver module according to the first embodiment. As illustrated in FIG. 3, the row decoder module 15 includes a plurality of row decoders RD (RD0, RD1, . . . ). The number of row decoders RD corresponds to the number of blocks BLK. Each of the plurality of row decoders RD has a comparable configuration. In the example of FIG. 3, the configuration of the row decoder RD0 corresponding to the block BLK0 is illustrated. The row decoder RD0 includes block decoders BD_C, BD_U, and BD_L, and transfer switches WLSW_C, WLSW_U, and WLSW_L. Note that the block decoders BD_C, BD_U, and BD_L may also be regarded as one block decoder or one decoder.

### 1.1.4.1 Transfer Switch

First, the configurations of the transfer switches WLSW_C, WLSW_U, and WLSW_L will be described with reference to FIG. 3.

The transfer switch WLSW_C includes transistors TR0, TR1, . . . , TR6, and TR7. Each of the transistors TR0 to TR7 is, for example, an N-type transistor. First ends of the transistors TR0 to TR7 are connected to the block BLK0 through the word lines WL0 to WL7, respectively. Second ends of the transistors TR0 to TR7 are connected to the driver module 14 through wirings CG0 to CG7, respectively. Gates of the transistors TR0 to TR7 are connected to the block decoder BD_C through a node BLKSEL_C.

For example, in the write operation, the transistors TR0 to TR7 may transfer write voltages to the word lines WL0 to WL7, respectively. The write voltage is a high voltage that can increase a threshold voltage of the memory cell transistor MT. Therefore, the transistors TR0 to TR7 have a withstand voltage high enough to transfer the write voltage. Hereinafter, a transistor having a withstand voltage high enough to transfer a write voltage is also referred to as a “high withstand voltage transistor”. For example, in the case of a transistor capable of operating up to 30 V, the high withstand voltage transistor is designed so that a film thickness of a gate oxide film is about 40 nm. In addition, a transistor having a lower withstand voltage than a transistor having a high withstand voltage is also referred to as a “low withstand voltage transistor” or simply a “transistor”.

The transfer switch WLSW_U includes transistors TR8, TR9, TR10, TR11, TR12, and TR13. Each of the transistors TR8 to TR10 is, for example, a high withstand voltage N-type transistor. Each of the transistors TR11 to TR13 is, for example, a low withstand voltage N-type transistor.

First ends of the transistors TR8, TR9, and TR10 are connected to the block BLK0 through the select gate lines SGS0, SGD0, and SGD1, respectively. Second ends of the transistors TR8, TR9, and TR10 are connected to the driver module 14 through wirings SGSD0, SGDD0, and SGDD1, respectively. A gate of each of the transistors TR8, TR9, and TR10 is connected to the block decoder BD_U through a node BLKSEL_U.

First ends of the transistors TR11, TR12, and TR13 are connected to the block BLK0 through the select gate lines SGS0, SGD0, and SGD1, respectively. A second end of the transistor TR11 is connected to the driver module 14 through a wiring USGS. Second ends of the transistors TR12 and TR13 are connected to the driver module 14 through a wiring USGD. A gate of each of the transistors TR11, TR12, and TR13 is connected to the block decoder BD_U through a node BLKSEL_Un.

The transfer switch WLSW_L includes transistors TR14, TR15, TR16, TR17, TR18, and TR19. Each of the transistors TR14 to TR16 is, for example, a high withstand voltage N-type transistor. Each of the transistors TR17 to TR19 is, for example, a low withstand voltage N-type transistor.

First ends of the transistors TR14, TR15, and TR16 are connected to the block BLK0 through select gate lines SGS1, SGD2, and SGD3, respectively. Second ends of the transistors TR14, TR15, and TR16 are connected to the driver module 14 through wirings SGSD1, SGDD2, and SGDD3, respectively. Gates of the transistors TR14, TR15, and TR16 are connected to the block decoder BD_L through a node BLKSEL_L.

First ends of the transistors TR17, TR18, and TR19 are connected to the block BLK0 through the select gate lines SGS1, SGD2, and SGD3, respectively. A second end of the transistor TR17 is connected to the driver module 14 through the wiring USGS. Second ends of the transistors TR18 and TR19 are connected to the driver module 14 through the wiring USGD. Gates of the transistors TR17, TR18, and TR19 are connected to the block decoder BD_L through a node BLKSEL_Ln.

### 1.1.4.2 Block Decoder

Next, configurations of the block decoders BD_C, BD_U, and BD_L will be described.

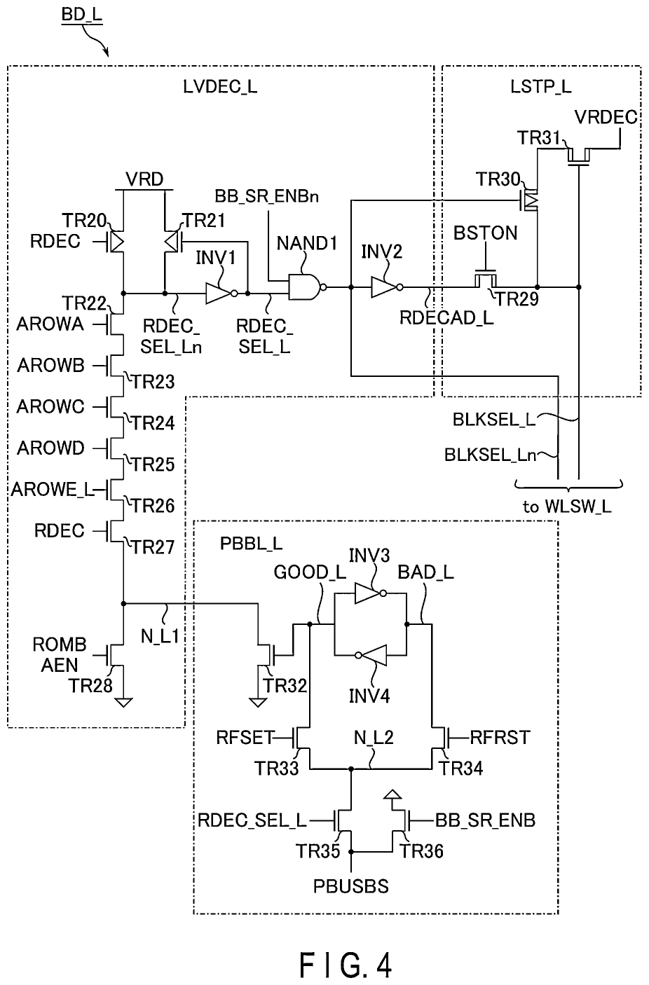

FIG. 4 is a circuit diagram illustrating an example of a configuration of a first portion of the block decoder according to the first embodiment. The first portion of the block decoder corresponds to the block decoder BD_L. As illustrated in FIG. 4, the block decoder BD_L includes a decoder LVDEC_L, a level shifter LSTP_L, and a partial bad block latch PBBL_L.

The decoder LVDEC_L includes transistors TR20, TR21, TR22, TR23, TR24, TR25, TR26, TR27, and TR28, inverters INV1 and INV2, and a logic circuit NAND1. The transistors TR20 and TR21 are, for example, P-type transistors. The transistors TR22 to TR28 are, for example, N-type transistors.

The transistor TR20 has a first end to which a voltage VRD is supplied, a second end connected to a node RDEC_SEL_Ln, and a gate connected to a node RDEC. The transistor TR21 has a first end to which the voltage VRD is supplied, a second end connected to the node RDEC_SEL_Ln, and a gate connected to a node RDEC_SEL_L. The voltage VRD corresponds to, for example, a logic level of the “H” level in the block decoders BD_L and BD_U.

The transistor TR22 has a first end connected to the node RDEC_SEL_Ln and a gate connected to a node AROWA. The transistor TR23 has a first end connected to a second end of the transistor TR22 and a gate connected to a node AROWB. The transistor TR24 has a first end connected to a second end of the transistor TR23 and a gate connected to a node AROWC. The transistor TR25 has a first end connected to a second end of the transistor TR24 and a gate connected to a node AROWD. The transistor TR26 has a first end connected to a second end of the transistor TR25 and a gate connected to a node AROWE_L.

The transistor TR27 has a first end connected to a second end of the transistor TR26, a second end connected to a node N_L1, and a gate connected to the node RDEC. The transistor TR28 has a first end connected to the node N_L1, a second end grounded, and a gate connected to a node ROMBAEN.

The inverter INV1 has an input terminal connected to the node RDEC_SEL_Ln and an output terminal connected to the node RDEC_SEL_L. That is, the inverter INV1 inverts a logic level of the node RDEC_SEL_Ln and outputs the inverted logic level to the node RDEC_SEL_L.

The logic circuit NAND1 includes a first input terminal connected to the node RDEC_SEL_L, a second input terminal connected to a node BB_SR_ENBn, and an output terminal connected to the node BLKSEL_Ln. That is, the logic circuit NAND1 executes NAND operation of the logic level of the node RDEC_SEL_L and the logic level of the node BB_SR_ENBn, and outputs the execution result to the node BLKSEL_Ln.

The inverter INV2 has an input end connected to the node BLKSEL_Ln and an output end connected to a node RDECAD_L. That is, the inverter INV2 inverts the logic level of the node BLKSEL_Ln and outputs the inverted logic level to the node RDECAD_L.

The level shifter LSTP_L includes transistors TR29, TR30, and TR31. The transistors TR29 and TR31 are, for example, high withstand voltage N-type transistors. The transistor TR30 is, for example, a high withstand voltage P-type transistor.

The transistor TR29 has a first end connected to the node RDECAD_L, a second end connected to the node BLKSEL_L, and a gate connected to a node BSTON. The transistor TR30 has a first end connected to the node BLKSEL_L and a gate connected to the node BLKSEL_Ln. The transistor TR31 has a first end connected to a second end of the transistor TR30, a second end to which a voltage VRDEC is supplied, and a gate connected to the node BLKSEL_L. The voltage VRDEC is a voltage having such a height that a high withstand voltage transistor in the transfer switches WLSW_C, WLSW_L, and WLSW_U can be turned on when a high voltage such as a write voltage is transferred to the memory cell array 10.

The partial bad block latch PBBL_L includes transistors TR32, TR33, TR34, TR35, and TR36, and inverters INV3 and INV4. The transistors TR32 to TR36 are, for example, N-type transistors.

The transistor TR32 has a first end connected to the node N_L1, a second end grounded, and a gate connected to a node GOOD_L. The transistor TR33 has a first end connected to the node GOOD_L, a second end connected to a node N_L2, and a gate connected to a node RFSET. The transistor TR34 has a first end connected to a node BAD_L, a second end connected to the node N_L2, and a gate connected to the node RFRST.

The transistor TR35 has a first end connected to the node N_L2, a second end connected to a node PBUSBS, and a gate connected to the node RDEC_SEL_L. The transistor TR36 has a first end connected to the node PBUSBS, a second end grounded, and a gate connected to a node BB_SR_ENB.

The inverter INV3 has an input end connected to the node GOOD_L and an output end connected to the node BAD_L. That is, the inverter INV3 inverts the logic level of the node GOOD_L and outputs the inverted logic level to the node BAD_L. The inverter INV4 has an input end connected to the node BAD_L and an output end connected to the node GOOD_L. That is, the inverter INV4 inverts the logic level of the node BAD_L and outputs the inverted logic level to the node GOOD_L.

In a case where the corresponding partial block PBLK_L is in a good state, the logic level of the node GOOD_L and the logic level of the node BAD_L of the partial bad block latch PBBL_L are “H” and “L”, respectively. In a case where the corresponding partial block PBLK_L is in the bad state, the logic level of the node GOOD_L and the logic level of the node BAD_L of the partial bad block latch PBBL_L are “L” and “H”, respectively.

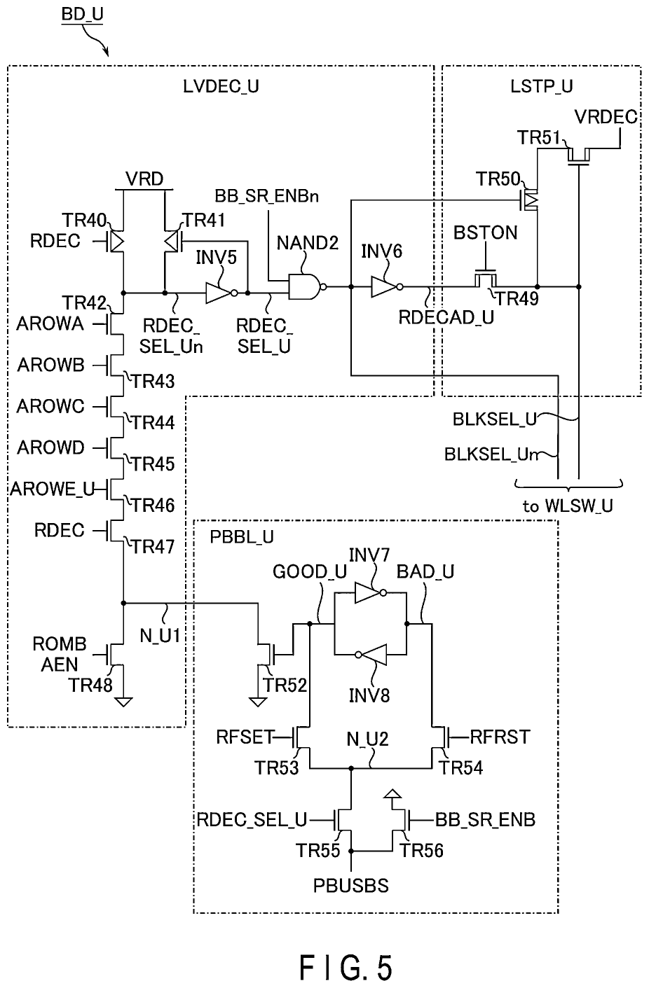

FIG. 5 is a circuit diagram illustrating an example of a configuration of a second portion of the block decoder according to the first embodiment. The second portion of the block decoder corresponds to the block decoder BD_U. As illustrated in FIG. 5, the block decoder BD_U includes a decoder LVDEC_U, a level shifter LSTP_U, and a partial bad block latch PBBL_U.

The decoder LVDEC_U includes transistors TR40, TR41, TR42, TR43, TR44, TR45, TR46, TR47, and TR48, inverters INV5 and INV6, and a logic circuit NAND2. The transistors TR40 and TR41 are, for example, P-type transistors. The transistors TR42 to TR48 are, for example, N-type transistors.

The transistor TR40 has a first end to which the voltage VRD is supplied, a second end connected to a node RDEC_SEL_Un, and a gate connected to the node RDEC. The transistor TR41 has a first end to which the voltage VRD is supplied, a second end connected to a node RDEC_SEL_Un, and a gate connected to a node RDEC_SEL_U.

The transistor TR42 has a first end connected to the node RDEC_SEL_Un and a gate connected to the node AROWA. The transistor TR43 has a first end connected to a second end of the transistor TR42 and a gate connected to the node AROWB. The transistor TR44 has a first end connected to a second end of the transistor TR43 and a gate connected to the node AROWC. The transistor TR45 has a first end connected to a second end of the transistor TR44 and a gate connected to the node AROWD. The transistor TR46 has a first end connected to a second end of the transistor TR45 and a gate connected to a node AROWE_U.

The transistor TR47 has a first end connected to a second end of the transistor TR46, a second end connected to a node N_U1, and a gate connected to the node RDEC. The transistor TR48 has a first end connected to the node N_U1, a second end grounded, and a gate connected to the node ROMBAEN.

The inverter INV5 has an input terminal connected to the node RDEC_SEL_Un and an output terminal connected to the node RDEC_SEL_U. That is, the inverter INV5 inverts the logic level of the node RDEC_SEL_Un and outputs the inverted logic level to the node RDEC_SEL_U.

The logic circuit NAND2 includes a first input terminal connected to the node RDEC_SEL_U, a second input terminal connected to the node BB_SR_ENBn, and an output terminal connected to the node BLKSEL_Un. That is, the logic circuit NAND2 executes the NAND operation of the logic level of the node RDEC_SEL_U and the logic level of the node BB_SR_ENBn, and outputs the execution result to the node BLKSEL_Un.

The inverter INV6 has an input end connected to the node BLKSEL_Un and an output end connected to a node RDECAD_U. That is, the inverter INV6 inverts the logic level of the node BLKSEL_Un and outputs the inverted logic level to the node RDECAD_U.

The level shifter LSTP_U includes transistors TR49, TR50, and TR51. The transistors TR49 and TR51 are, for example, high withstand voltage N-type transistors. The transistor TR50 is, for example, a high withstand voltage P-type transistor.

The transistor TR49 has a first end connected to the node RDECAD_U, a second end connected to the node BLKSEL_U, and a gate connected to the node BSTON. The transistor TR50 has a first end connected to the node BLKSEL_U and a gate connected to the node BLKSEL_Un. The transistor TR51 has a first end connected to a second end of the transistor TR50, a second end to which the voltage VRDEC is supplied, and a gate connected to the node BLKSEL_U.

The partial bad block latch PBBL_U includes transistors TR52, TR53, TR54, TR55, and TR56, and inverters INV7 and INV8. The transistors TR52 to TR56 are, for example, N-type transistors.

The transistor TR52 has a first end connected to the node N_U1, a second end grounded, and a gate connected to a node GOOD_U. The transistor TR53 has a first end connected to the node GOOD_U, a second end connected to a node N_U2, and a gate connected to the node RFSET. The transistor TR54 has a first end connected to a node BAD_U, a second end connected to the node N_U2, and a gate connected to a node RFRST.

The transistor TR55 has a first end connected to the node N_U2, a second end connected to the node PBUSBS, and a gate connected to the node RDEC_SEL_U. The transistor TR56 has a first end connected to the node PBUSBS, a second end grounded, and a gate connected to the node BB_SR_ENB.

The inverter INV7 has an input end connected to the node GOOD_U and an output end connected to the node BAD_U. That is, the inverter INV7 inverts the logic level of the node GOOD_U and outputs the inverted logic level to the node BAD_U. The inverter INV8 has an input end connected to the node BAD_U and an output end connected to the node GOOD_U. That is, the inverter INV8 inverts the logic level of the node BAD_U and outputs the inverted logic level to the node GOOD_U.

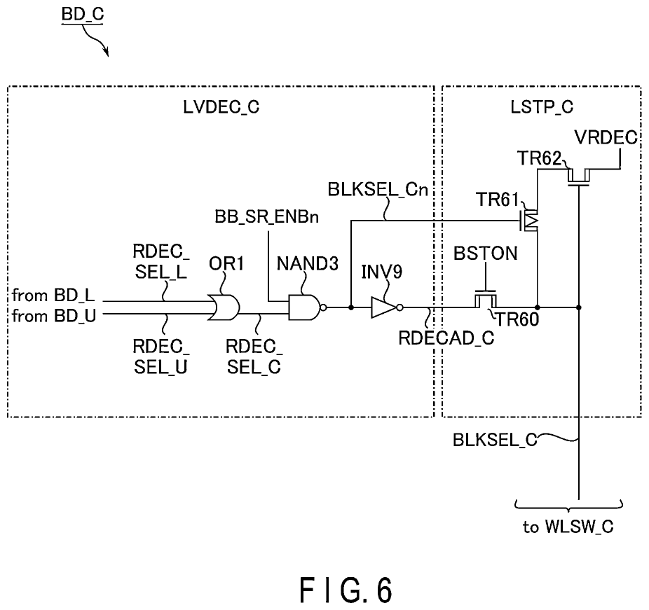

FIG. 6 is a circuit diagram illustrating an example of a configuration of a third portion of the block decoder according to the first embodiment. The third portion of the block decoder corresponds to the block decoder BD_C. As illustrated in FIG. 6, the block decoder BD_C includes a decoder LVDEC_C and a level shifter LSTP_C.

The decoder LVDEC_C includes logic circuits OR1 and NAND3, and an inverter INV9.

The logic circuit OR1 has a first input terminal connected to the node RDEC_SEL_L, a second input terminal connected to the node RDEC_SEL_U, and an output terminal connected to a node RDEC_SEL_C. That is, the logic circuit OR1 performs an OR operation of the logic level of the node RDEC_SEL_L and the logic level of the node RDEC_SEL_U, and outputs the execution result to the node RDEC_SEL_C.

The logic circuit NAND3 has a first input terminal connected to the node RDEC_SEL_C, a second input terminal connected to the node BB_SR_ENBn, and an output terminal connected to a node BLKSEL_Cn. That is, the logic circuit NAND3 executes the NAND operation of the logic level of the node RDEC_SEL_C and the logic level of the node BB_SR_ENBn, and outputs the execution result to the node BLKSEL_Cn.

The inverter INV9 has an input end connected to the node BLKSEL_Cn and an output end connected to a node RDECAD_C. That is, the inverter INV9 inverts the logic level of the node BLKSEL_Cn and outputs the inverted logic level to the node RDECAD_C.

The level shifter LSTP_C includes transistors TR60, TR61, and TR62. The transistors TR60 and TR62 are, for example, high withstand voltage N-type transistors. The transistor TR61 is, for example, a high withstand voltage P-type transistor.

The transistor TR60 has a first end connected to the node RDECAD_C, a second end connected to the node BLKSEL_C, and a gate connected to the node BSTON. The transistor TR61 has a first end connected to the node BLKSEL_C and a gate connected to the node BLKSEL_Cn. The transistor TR62 has a first end connected to a second end of the transistor TR61, a second end to which the voltage VRDEC is supplied, and a gate connected to the node BLKSEL_C.

### 1.1.5 Structure of Memory Device

Next, an example of a structure of the memory device according to the first embodiment will be described.

### 1.1.5.1 Bonding Structure

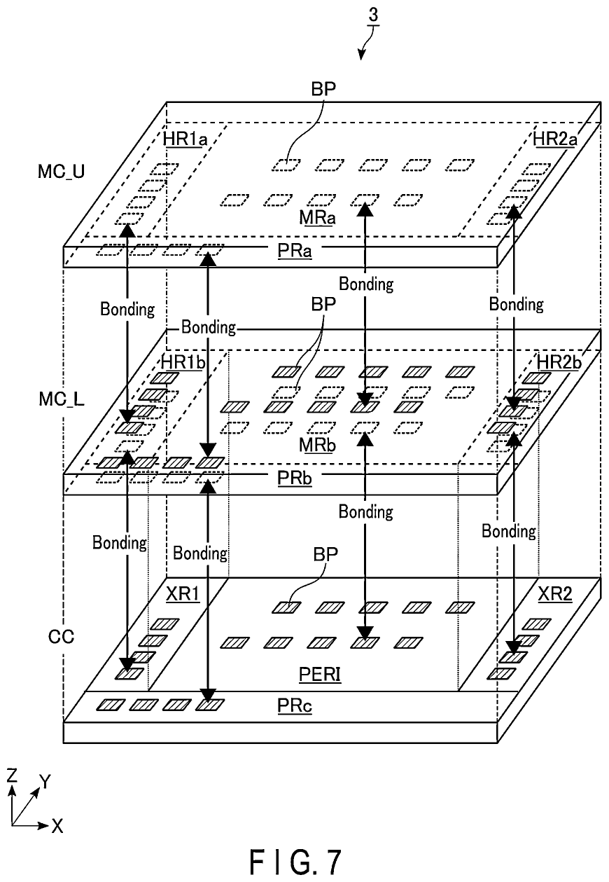

FIG. 7 is a perspective view illustrating an example of a bonding structure of the memory device according to the first embodiment. As illustrated in FIG. 7, the memory device 3 includes a memory chip MC_U, a memory chip MC_L, and a circuit chip CC. The memory device 3 is formed by bonding the memory chip MC_U and the circuit chip CC to the memory chip MC_L so as to sandwich the memory chip MC_L. The memory chip MC_U and the memory chip MC_L, and the memory chip MC_L and the circuit chip CC are bonded by a plurality of bonding pads BP.

The memory chip MC_U and the memory chip MC_L include a structure corresponding to the memory cell array 10. The circuit chip CC includes, for example, a structure corresponding to the command register 11, the address register 12, the sequencer 13, the driver module 14, the row decoder module 15, and the sense amplifier module 16.

Hereinafter, a surface on which the circuit chip CC and the memory chip MC_L are bonded is referred to as an XY plane. The plane on which the memory chip MC_U and the memory chip MC_L are bonded is substantially parallel to the XY plane. The directions intersecting each other in the XY plane are defined as an X direction and a Y direction. In addition, a direction from the circuit chip CC to the memory chip MC_L is defined as a Z1 direction or an upward direction. On the other hand, a direction from the memory chip MC_L toward the circuit chip CC is defined as a Z2 direction or a downward direction. In a case where it is not distinguished whether the direction is the Z1 direction or the Z2 direction, the direction is simply referred to as the Z direction.

A region of the memory chip MC_U is divided into, for example, a memory region MRa, hookup regions HR1a and HR2a, and a pad region PRa. The memory region MRa corresponds to a region in which a part of the memory cell array 10 is formed. The hookup regions HR1a and HR2a are regions from which various wirings such as the word line WL connected to a part of the memory cell array 10 formed in the memory region MRa are led out. The pad region PRa is a region where a power supply pad for supplying a power supply voltage or the like to the memory chip MC_U is formed. The hookup regions HR1a and HR2a sandwich the memory region MRa in the X direction, for example. The pad region PRa is aligned in the Y direction with the memory region MRa and the hookup regions HR1a and HR2a.

The region of the memory chip MC_L is divided into, for example, a memory region MRb, hookup regions HR1b and HR2b, and a pad region PRb. The memory region MRb corresponds to a region in which a part of the memory cell array 10 is formed. The hookup regions HR1b and HR2b are regions from which various wirings such as the word line WL connected to a part of the memory cell array 10 formed in the memory region MRb are led out. The pad region PRb is a region where a power supply pad for supplying a power supply voltage or the like to the memory chip MC_L is formed. The memory region MRb is arranged so as to overlap the memory region MRa when viewed in the Z direction. The hookup regions HR1b and HR2b sandwich the memory region MRb in the X direction, for example. The hookup regions HR1b and HR2b are disposed so as to overlap the hookup regions HR1a and HR2a, respectively, when viewed in the Z direction. The pad region PRb is aligned in the Y direction with the memory region MRb and the hookup regions HR1b and HR2b. The pad region PRb is disposed so as to overlap the pad region PRa when viewed in the Z direction.

The region of the circuit chip CC is divided into, for example, a peripheral circuit region PERI, transfer regions XR1 and XR2, and a pad region PRc. In the peripheral circuit region PERI, the command register 11, the address register 12, the sequencer 13, the sense amplifier module 16, and the like are arranged. The peripheral circuit region PERI is arranged so as to overlap the memory regions MRa and MRb when viewed in the Z direction. The driver module 14, the row decoder module 15, and the like are arranged in the transfer regions XR1 and XR2. The transfer regions XR1 and XR2 sandwich the peripheral circuit region PERI in the X direction. The transfer regions XR1 and XR2 are arranged so as to overlap the hookup regions HR1a and HR1b and HR2a and HR2b, respectively, when viewed in the Z direction. In the pad region PRc, an input/output circuit and the like of the memory device 3 are arranged. The pad region PRc is disposed so as to overlap the pad regions PRa and PRb when viewed in the Z direction.

A set of two bonding pads BP facing each other between the memory chip MC_U and the memory chip MC_L are bonded. A set of two bonding pads BP facing each other between the memory chip MC_L and the circuit chip CC are bonded (“bonding” in FIG. 7). As a result, the circuit in the memory chip MC_U, the circuit in the memory chip MC_L, and the circuit in the circuit chip CC are electrically connected.

In the following description, the memory regions MRa and MRb may be referred to as memory regions MR unless otherwise distinguished. The hookup regions HR1a and HR1b may be referred to as a hookup region HR1 unless otherwise distinguished. In a case where not particularly distinguished, the hookup regions HR2a and HR2b may be referred to as a hookup region HR2. In a case of being not particularly distinguished, the hookup regions HR1a and HR2a may be referred to as a hookup region HRa. In a case of being not particularly distinguished, the hookup regions HR1b and HR2b may be referred to as a hookup region HRb.

Note that the memory device 3 according to the first embodiment is not limited to the structure described above. For example, the number of the hookup regions HR provided in each of the memory chip MC_U and the memory chip MC_L may be the same and is not limited to two. Each of the memory chip MC_U and the memory chip MC_L may include a plurality of sets of the memory region MR and the hookup region HR. In this case, the pair of the peripheral circuit region PERI and the transfer region XR is appropriately provided corresponding to the arrangement of the memory region MR and the hookup region HR.

### 1.1.5.2 Cross-Sectional Structure

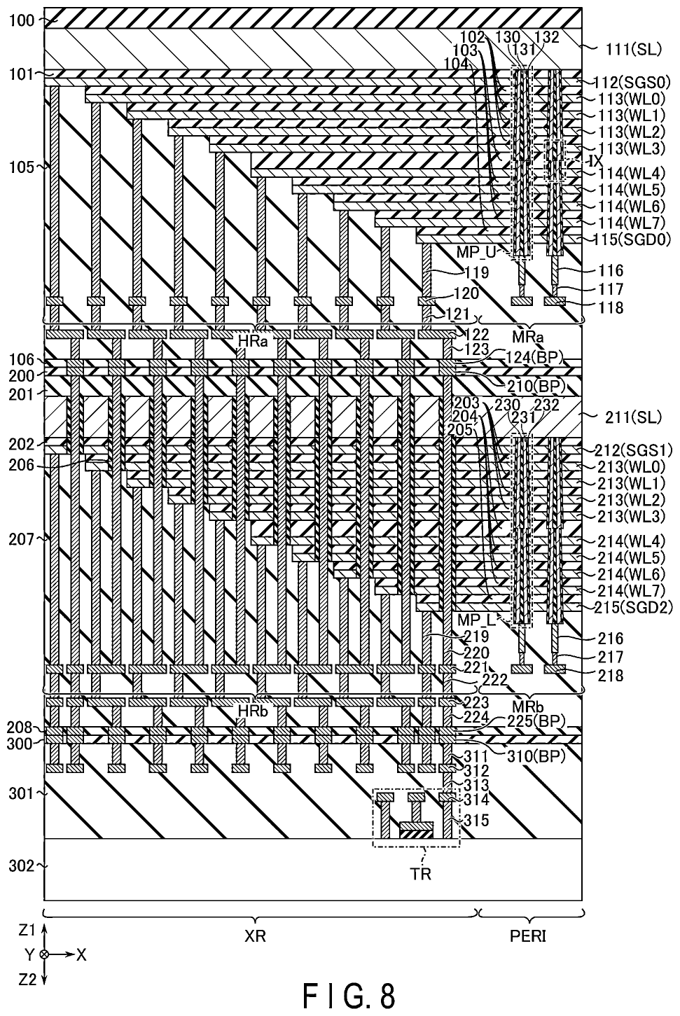

FIG. 8 is a cross-sectional view illustrating an example of a cross-sectional structure of the memory device according to the first embodiment. FIG. 8 illustrates an example of a cross section including the memory region MR and the peripheral circuit region PERI of the memory device 3 and a cross section including the hookup region HR and the transfer region XR. The memory regions MRa and MRb illustrated in FIG. 8 correspond to the string units SU0 and SU2 in the same block BLK, respectively.

### (Memory Chip MC_U)

First, the configuration of the memory chip MC_U will be described.

A conductor layer 111 is provided on a lower surface of an insulator layer 100. The conductor layer 111 is formed in, for example, a plate shape extending along the XY plane. The conductor layer 111 is used as the source line SL. The conductor layer 111 contains, for example, polysilicon. The insulator layer 100 includes, for example, an insulator such as silicon oxide.

A conductor layer 112 is provided below the conductor layer 111 with an insulator layer 101 interposed therebetween. The conductor layer 112 is formed in, for example, a plate shape extending along the XY plane. The conductor layer 112 is used as the select gate line SGS0. The conductor layer 112 contains, for example, tungsten. The insulator layer 101 includes, for example, an insulator such as silicon oxide.

Below the conductor layer 112, insulator layers 102 and conductor layers 113 are alternately stacked in this order downward. The conductor layer 113 is formed in, for example, a plate shape extending along the XY plane. The plurality of conductor layers 113 is used as the word lines WL0 to WL3 in order from the insulator layer 100 side. The conductor layer 113 contains, for example, tungsten. The insulator layer 102 includes, for example, an insulator such as silicon oxide.

Below the lowermost conductor layer 113, insulator layers 103 and conductor layers 114 are alternately stacked in this order downward. The insulator layer 103 provided between the lowermost conductor layer 113 and the uppermost conductor layer 114 has, for example, a film thickness thicker than that of the other insulator layers 103. The conductor layer 114 is formed in, for example, a plate shape extending along the XY plane. The plurality of conductor layers 114 is used as the word lines WL4 to WL7, respectively, in order from the insulator layer 100 side. The conductor layer 114 contains, for example, tungsten. The insulator layer 103 includes, for example, an insulator such as silicon oxide.

A conductor layer 115 is provided below the lowermost conductor layer 114 with an insulator layer 104 interposed therebetween. The conductor layer 115 is formed in, for example, a plate shape extending along the XY plane. The conductor layer 115 is used as the select gate line SGD0. The conductor layer 115 contains, for example, tungsten. The insulator layer 104 includes, for example, an insulator such as silicon oxide.

The conductor layers 112, 113, 114, and 115 as described above form a stacked wiring structure of the memory chip MC_U.

In the memory region MRa, a memory pillar MP_U is provided so as to penetrate the stacked wiring structure of the memory chip MC_U. The memory pillar MP_U extends in the Z direction. An upper end of the memory pillar MP_U is in contact with the conductor layer 111. A lower end of the memory pillar MP_U is located below the conductor layer 115.

The memory pillar MP_U is a member including a core film 130, a semiconductor film 131, and a stacked film 132.

The core film 130 extends in the Z direction. An upper end of the core film 130 is positioned, for example, above the conductor layer 112. A lower end of the core film 130 is positioned below the conductor layer 115. The core film 130 includes, for example, an insulator such as silicon oxide.

The semiconductor film 131 covers a periphery of the core film 130. In an upper portion of the memory pillar MP_U, the semiconductor film 131 is in contact with the conductor layer 111. The semiconductor film 131 contains, for example, silicon.

The stacked film 132 covers a side surface and an upper surface of the semiconductor film 131 except for a portion where the semiconductor film 131 and the conductor layer 111 are in contact with each other.

A portion where the memory pillar MP_U intersects the conductor layer 112 functions as the select transistor ST2. Portions where the memory pillars MP_U intersect with the plurality of conductor layers 113 function as the memory cell transistors MT0 to MT3, respectively. Portions where the memory pillars MP_U intersect with the plurality of conductor layers 114 function as the memory cell transistors MT4 to MT7, respectively. A portion where the memory pillar MP_U intersects the conductor layer 115 functions as the select transistor ST1.

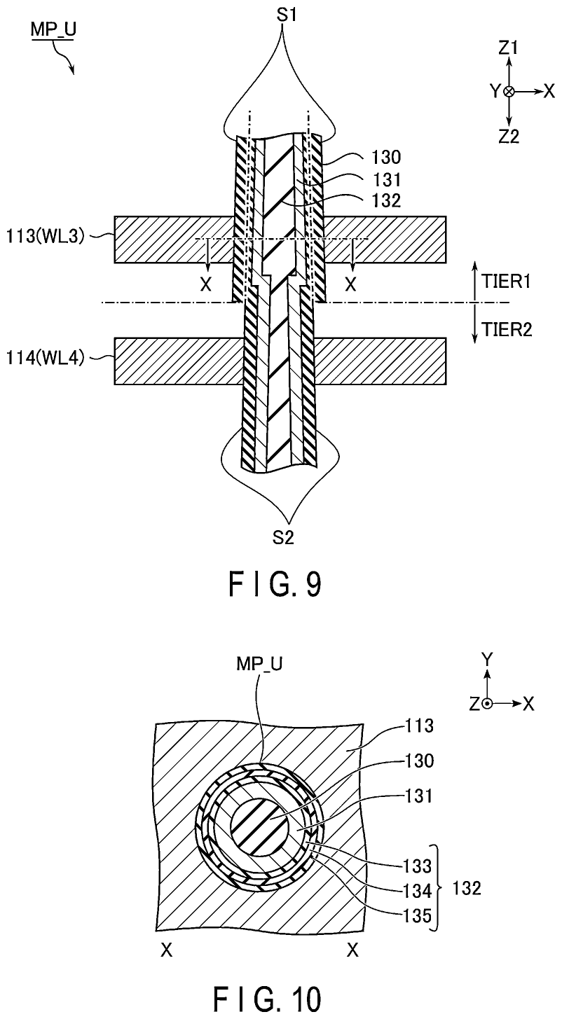

FIG. 9 is a cross-sectional view illustrating an example of a cross-sectional structure of the memory pillar of the memory device corresponding to the region IX in FIG. 8 according to the first embodiment. In FIG. 9, the structure between the lowermost conductor layer 113 and the uppermost conductor layer 114 of the memory pillars MP_U is mainly illustrated.

As illustrated in FIG. 9, the memory pillar MP_U can be classified into two sub-members of an upper portion TIER1 and a lower portion TIER2 with a boundary between the lowermost conductor layer 113 and the uppermost conductor layer 114. A diameter of the memory pillar MP_U may change discontinuously at the boundary between the upper portion TIER1 and the lower portion TIER2. Specifically, a diameter at the lower end of the upper portion TIER1 is larger than a diameter at the upper end of the lower portion TIER2. A side surface S1 of the upper portion TIER1 and extension of a side surface S2 of the lower portion TIER2 are shifted from each other and do not coincide with each other. Such a shift between the side surface S1 of the upper portion TIER1 and the extension of the side surface S2 of the lower portion TIER2 occurs not only in the cross section illustrated in FIG. 9 but also in any cross section including the Z direction.

FIG. 10 is a cross-sectional view taken along line X-X of FIG. 9, illustrating an example of a cross-sectional structure of the memory cell transistor in the memory device according to the first embodiment. More specifically, FIG. 10 illustrates a cross-sectional structure of the memory pillar MP_U in the layer including the conductor layer 113. As illustrated in FIG. 10, the stacked film 132 includes a tunnel insulating film 133, a charge storage film 134, and a block insulating film 135.

In the cross section including the conductor layer 113, the core film 130 is provided, for example, at the central portion of the memory pillar MP_U. The semiconductor film 131 surrounds a side surface of the core film 130. The tunnel insulating film 133 surrounds a side surface of the semiconductor film 131. The charge storage film 134 surrounds a side surface of the tunnel insulating film 133. The block insulating film 135 surrounds a side surface of the charge storage film 134. The conductor layer 113 surrounds a side surface of the block insulating film 135.

The tunnel insulating film 133 and the block insulating film 135 include, for example, silicon oxide. The charge storage film 134 includes, for example, silicon nitride.

The configuration of the memory chip MC_U will be described with reference to FIG. 8 again.

A lower surface of the semiconductor film 131 in the memory pillar MP_U is connected to one conductor layer 118 through conductors 116 and 117 extending in the Z direction. The conductors 116 and 117 are used, for example, as contacts. The conductor layer 118 is formed in a line shape extending in the Y direction, for example, and is used as the bit line BL. That is, in a region (not illustrated), the conductor layers 118 are arranged in a plurality of rows in the X direction. The conductor layer 118 contains, for example, copper.

In the hookup region HRa, an end portion of the stacked wiring structure of the memory chip MC_U is provided stepwise in the X direction. Hereinafter, among the end portions of the stacked wiring structure provided in a stepwise manner, a portion that does not overlap the conductor layer of the lower layer when viewed in the Z direction is also referred to as a terrace portion. In the example of FIG. 8, a case where the terrace portions of the conductor layers 112 to 115 are arranged in the X direction is illustrated.

A plurality of conductors 119 is provided on the lower surface of each terrace portion of the conductor layer 112 to 115 configuring the stacked wiring structure of the memory chip MC_U. Each of the plurality of conductors 119 is used as a contact extending in the Z direction.

A plurality of conductor layers 120 is provided on the lower surfaces of the plurality of conductors 119, respectively. The plurality of conductor layers 120 is provided, for example, at positions substantially equal to the plurality of conductor layers 118 in the Z direction.

A plurality of conductors 121 is provided on the lower surfaces of the plurality of conductor layers 120, respectively. Each of the plurality of conductors 121 is used as a contact extending in the Z direction.

A plurality of conductor layers 122 is provided on lower surfaces of the plurality of conductors 121, respectively.

A plurality of conductors 123 is provided on lower surfaces of the plurality of conductor layers 122, respectively. Each of the plurality of conductors 123 is used as a contact extending in the Z direction.

A plurality of electrodes 124 is provided on lower surfaces of the plurality of conductors 123, respectively. The plurality of electrodes 124 are used as bonding pads BP of the memory chip MC_U. The plurality of electrodes 124 contains, for example, copper.

An insulator layer 105 covers the stacked wiring structure of the memory chip MC_U, the conductors 116, 117, 119, 121, and 123, and the side surfaces of the conductor layers 118, 120, and 122. A lower surface of the insulator layer 105 is aligned with, for example, the lower surfaces of the plurality of conductors 123.

An insulator layer 106 is provided on the lower surface of the insulator layer 105. The insulator layer 106 covers side surfaces of the plurality of electrodes 124. A lower surface of the insulator layer 106 is aligned with, for example, lower surfaces of the plurality of electrodes 124.

### (Memory Chip MC_L)

Next, the configuration of the memory chip MC_L will be described.

The insulator layer 200 and the plurality of electrodes 210 are provided on the lower surface of the insulator layer 106 and the lower surfaces of the plurality of electrodes 124, respectively. The plurality of electrodes 210 are used as the bonding pads BP on the memory chip MC_U side of the memory chip MC_L. The lower surfaces of the plurality of electrodes 210 are aligned with, for example, the lower surface of the insulator layer 200. The plurality of electrodes 210 contains, for example, copper.

A conductor layer 211 is provided below the insulator layer 200 with an insulator layer 201 interposed therebetween. The conductor layer 211 is formed in, for example, a plate-like shape having an opening extending along the XY plane. The conductor layer 211 is used as the source line SL. The conductor layer 211 contains, for example, polysilicon. The insulator layer 201 includes, for example, an insulator such as silicon oxide.

A conductor layer 212 is provided below the conductor layer 211 with an insulator layer 202 interposed therebetween. The conductor layer 212 is formed in, for example, a plate shape extending along the XY plane. The conductor layer 212 is used as the select gate line SGS1. The conductor layer 212 contains, for example, tungsten. The insulator layer 202 includes, for example, an insulator such as silicon oxide.

Below the conductor layer 212, insulator layers 203 and conductor layers 213 are alternately stacked in this order downward. The conductor layer 213 is formed in, for example, a plate shape extending along the XY plane. The plurality of conductor layers 213 is used as the word lines WL0 to WL3 in order from the insulator layer 200 side. The conductor layer 213 contains, for example, tungsten. The insulator layer 203 includes, for example, an insulator such as silicon oxide.

Below the lowermost conductor layer 213, insulator layers 204 and conductor layers 214 are alternately stacked in this order downward. The insulator layer 204 provided between the lowermost conductor layer 213 and the uppermost conductor layer 214 has, for example, a film thickness thicker than that of the other insulator layers 204. The conductor layer 214 is formed in, for example, a plate shape extending along the XY plane. The plurality of conductor layers 214 is used as the word lines WL4 to WL7, respectively, in order from the insulator layer 200 side. The conductor layer 214 contains, for example, tungsten. The insulator layer 204 includes, for example, an insulator such as silicon oxide.

A conductor layer 215 is provided below the lowermost conductor layer 214 with an insulator layer 205 interposed therebetween. The conductor layer 215 is formed in, for example, a plate shape extending along the XY plane. The conductor layer 215 is used as the select gate line SGD2. The conductor layer 215 contains, for example, tungsten. The insulator layer 205 includes, for example, an insulator such as silicon oxide.

The conductor layers 212, 213, 214, and 215 as described above form a stacked wiring structure of the memory chip MC_L.

In the memory region MRb, a memory pillar MP_L is provided so as to penetrate the stacked wiring structure of the memory chip MC_L. The memory pillar MP_L includes a core film 230, a semiconductor film 231, and a stacked film 232, and extends in the Z direction. An upper end of the memory pillar MP_L is in contact with the conductor layer 211. A lower end of the memory pillar MP_L is located below the conductor layer 215. Since the configuration of the memory pillar MP_L is equivalent to the configuration of the memory pillar MP_U, the description thereof will be omitted.

A portion where the memory pillar MP_L intersects the conductor layer 212 functions as the select transistor ST2. Portions where the memory pillar MP_L intersects with the plurality of conductor layers 213 function as the memory cell transistors MT0 to MT3, respectively. Portions where the memory pillar MP_L intersects with the plurality of conductor layers 214 function as the memory cell transistors MT4 to MT7, respectively. A portion where the memory pillar MP_L intersects the conductor layer 215 functions as the select transistor ST1.

A lower surface of the semiconductor film 231 in the memory pillar MP_L is connected to one conductor layer 218 through conductors 216 and 217 extending in the Z direction. The conductors 216 and 217 are used, for example, as contacts. The conductor layer 218 is formed in a line shape extending in the Y direction, for example, and is used as the bit line BL. That is, in a region (not illustrated), the conductor layers 218 are arranged in a plurality of rows in the X direction. The conductor layer 218 contains, for example, copper.

In the hookup region HRb, an end portion of the stacked wiring structure of the memory chip MC_L is provided stepwise in the X direction.

A plurality of conductors 219 is provided on the lower surface of each terrace portion of the conductor layer 212 to 215 configuring the stacked wiring structure of the memory chip MC_L. Each of the plurality of conductors 219 is used as a contact extending in the Z direction.

In the hookup region HRb, a plurality of conductors 220 is provided on lower surfaces of the plurality of electrodes 210. The plurality of conductors 220 extend in the Z direction so as to penetrate the conductor layer 211 and the stacked wiring structure of the memory chip MC_L. Lower surfaces of the plurality of conductors 220 are aligned with, for example, lower surfaces of the plurality of conductors 219.

An insulator 206 is provided between each of the plurality of conductors 220 and the stacked wiring structure of the conductor layer 211 and the memory chip MC_L. As a result, each of the plurality of conductors 220 and the stacked wiring structure of the conductor layer 211 and the memory chip MC_L are electrically insulated.

In the hookup region HRb, the plurality of conductor layers 221 is provided at positions substantially equal to the plurality of conductor layers 218 in the Z direction. The plurality of conductor layers 221 is provided corresponding to the select gate lines SGS0 and SGS1, the word lines WL0 to WL7, and the select gate lines SGD0 to SGD3, respectively. That is, the number of the plurality of conductor layers 221 is fourteen. On the other hand, the number of the plurality of conductors 219 is eleven corresponding to the select gate line SGS1, the word lines WL0 to WL7 provided in the memory chip MC_L, and the select gate lines SGD2 and SGD3. The number of the plurality of conductors 220 is eleven corresponding to the select gate line SGS0, the word lines WL0 to WL7 provided in the memory chip MC_U, and the select gate lines SGD0 and SGD1. In the example of FIG. 8, the conductor 220 and the conductor layer 221 corresponding to the select gate line SGD1, and the conductor 219 and the conductor layer 221 corresponding to the select gate line SGD3 are not illustrated.

In the first embodiment, for each of the word lines WL0 to WL7, the conductor 219 and the conductor 220 corresponding to the same word line WL are connected to one conductor layer 221. The three conductors 219 corresponding to the select gate lines SGS1, SGD2, and SGD3 and the three conductors 220 corresponding to the select gate lines SGS0, SGD0, and SGD1 are connected to the six conductor layers 221 different from each other. These fourteen conductor layers 221 are electrically insulated from each other.

A plurality of conductors 222 is provided on lower surfaces of the plurality of conductor layers 221, respectively. Each of the plurality of conductors 222 is used as a contact extending in the Z direction.

A plurality of conductor layers 223 is provided on lower surfaces of the plurality of conductors 222, respectively.

A plurality of conductors 224 is provided on lower surfaces of the plurality of conductor layers 223, respectively. Each of the plurality of conductors 224 is used as a contact extending in the Z direction.

A plurality of electrodes 225 is provided on lower surfaces of the plurality of conductors 224, respectively. The plurality of electrodes 225 is used as the bonding pads BP on the circuit chip CC side of the memory chip MC_L. The plurality of electrodes 225 contains, for example, copper.

An insulator layer 207 covers the stacked wiring structure of the memory chip MC_L, the conductors 216, 217, 219, 220, 222, and 224, and the side surfaces of the conductor layers 218, 221, and 223. A lower surface of the insulator layer 207 is aligned with, for example, lower surfaces of the plurality of conductors 224.

An insulator layer 208 is provided on the lower surface of the insulator layer 207. The insulator layer 208 covers side surfaces of the plurality of electrodes 225. A lower surface of the insulator layer 208 is aligned with, for example, the lower surfaces of the plurality of electrodes 225.

### (Circuit Chip CC)

Next, the configuration of the circuit chip CC will be described.

The insulator layer 300 and the plurality of electrodes 310 are provided on the lower surface of the insulator layer 208 and the lower surfaces of the plurality of electrodes 225, respectively. The plurality of electrodes 310 is used as bonding pads BP of the circuit chip CC. Lower surfaces of the plurality of electrodes 310 are aligned with, for example, a lower surface of the insulator layer 300. The plurality of electrodes 310 contains, for example, copper.

On a lower surface of the insulator layer 300, a semiconductor substrate 302 is provided through an insulator layer 301. The insulator layers 300 and 301 include, for example, an insulator such as silicon oxide. The semiconductor substrate 302 is, for example, polysilicon containing P-type impurities. For example, the transistor TR is formed on the semiconductor substrate 302. The transistor TR provided in the transfer region XR is used, for example, as an element in the row decoder module 15.

In the hookup region HRb, each of the plurality of electrodes 310 is connected to the transistor TR on the semiconductor substrate 302 through, for example, the conductor 311, the conductor layer 312, the conductor 313, the conductor layer 314, and the conductor 315.

With the above configuration, the select gate line SGS0, the word lines WL0 to WL7, and the select gate lines SGD0 and SGD1 formed in the memory chip MC_U, and the select gate line SGS1, the word lines WL0 to WL7, and the select gate lines SGD2 and SGD3 formed in the memory chip MC_L are drawn out to the row decoder module 15 formed in the circuit chip CC.

### 1.2 Operation

Next, an operation of the memory device according to the first embodiment will be described.

### 1.2.1 Set Operation of Partial Bad Block Information

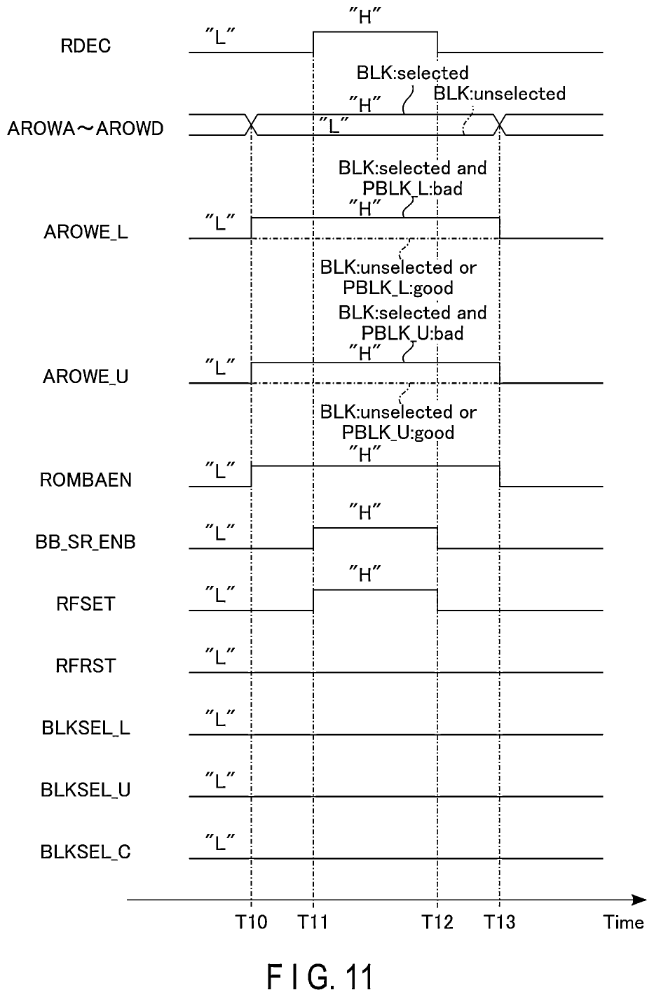

FIG. 11 is a timing chart illustrating an example of a set operation of partial bad block information in the memory device according to the first embodiment. In the set operation of the partial bad block information, the partial bad block information indicating that the partial block PBLK of a certain block BLK cannot be used is stored in the corresponding partial bad block latch PBBL. Hereinafter, it is assumed that the memory device 3 grasps the block address BAd of the partial block PBLK that is unusable (bad state) prior to the set operation of the partial bad block information.

At a time T10, the memory device 3 selects the block decoder BD to which the partial bad block information is set based on the block address BAd of the partial block PBLK that is found to be in the bad state. In other words, the memory device 3 selects the block decoder BD corresponding to the block BLK that has hit the block address BAd as the block decoder BD to set the partial bad block information.

Specifically, the memory device 3 sets the logic levels of the nodes AROWA, AROWB, AROWC, and AROWD of the block decoders BD_U and BD_L corresponding to the block BLK that has hit the block address BAd of the partial block PBLK that is known to be in the bad state to the “H” level. On the other hand, the memory device 3 sets the logic level of at least one node among the nodes AROWA, AROWB, AROWC, and AROWD of the block decoders BD_U and BD_L corresponding to the block BLK that has not hit the block address BAd to the “L” level.

In a case where the partial block PBLK_U is in the bad state, the memory device 3 sets the logic level of the node AROWE_U of the block decoder BD_U corresponding to the block BLK that has hit the block address BAd to the “H” level. In a case where the partial block PBLK_U is available (good state), the memory device 3 sets the logic level of the node AROWE_U of the block decoder BD_U corresponding to the block BLK that has hit the block address BAd to the “L” level.

Similarly, in a case where the partial block PBLK_L is in the bad state, the memory device 3 sets the logic level of the node AROWE_L of the block decoder BD_L corresponding to the block BLK that has hit the block address BAd to the “H” level. In a case where the partial block PBLK_L is in the good state, the memory device 3 sets the logic level of the node AROWE_L of the block decoder BD_L corresponding to the block BLK that has hit the block address BAd to the “L” level.

In addition, the memory device 3 changes the logic level of the node ROMBAEN from the “L” level to the “H” level. As a result, regardless of whether or not the partial bad block information is set in the partial bad block latches PBBL_L and PBBL_U, the logic levels of the nodes N_L1 and N_U1 become the “L” level. Note that an initial setting value (that is, the logical level before time T10) of the nodes N_L1 and N_U1 is at the “H” level.

At a time T11, the memory device 3 changes the logic level of the node RDEC from the “L” level to the “H” level. As a result, the logical levels of the node RDEC_SEL_Un of the block decoder BD_U corresponding to the block BLK that has hit the block address BAd and the node RDEC_SEL_Ln of the block decoder BD_L corresponding to the block BLK that has hit the block address BAd change from the “H” level to the “L” level.

In addition, the memory device 3 changes the logic level of the node BB_SR_ENB from the “L” level to the “H” level. As a result, the logical levels of the nodes BLKSEL_U, BLKSEL_L, and BLKSEL_C are maintained at the “L” level regardless of whether or not the block address BAd is hit. Therefore, all the blocks BLK go into a unselected state. That is, the select gate lines SGS and SGD of all the blocks BLK are connected to the wirings USGD and USGS, respectively. In addition, the word lines WL0 to WL7 of all the blocks BLK are in a floating state.

In addition, the memory device 3 changes the logic level of the node RFSET from the “L” level to the “H” level. As a result, the node GOOD_U in the block decoder BD_U corresponding to the partial block PBLK_U in the bad state and the block address BAd is hit, and the node GOOD_L in the block decoder BD_L corresponding to the partial block PBLK_L in the bad state and the block address BAd is hit go to the “L” level. Note that the node GOOD_U in the block decoder BD_U corresponding to the partial block PBLK_U in the good state or the block address BAd is not hit, and the node GOOD_L in the block decoder BD_L corresponding to the partial block PBLK_L in the good state or the block address BAd is not hit is at the “H” level.

At a time T12, the memory device 3 changes the logic levels of the nodes RDEC, BB_SR_ENB, and RESET from the “H” level to the “L” level. As a result, the selected states of the block decoders BD_U and BD_L are released, but the logic levels of the nodes GOOD_U and GOOD_L are maintained. Therefore, the partial bad block information can be stored in the corresponding partial bad block latch PBBL for each partial block PBLK.

At a time T13, the memory device 3 changes the logic levels of the nodes AROWA, AORWB, AROWC, AROWD, AROWE_U, AROWE_L, and ROMBAEN from the “H” level to the “L” level. As described above, the set operation of the partial bad block information ends. As a result, the logic levels of the nodes GOOD_U and GOOD_L corresponding to the partial blocks PBLK_U and PBLK_L in the good state are set to the “H” level, and the logic levels of the nodes GOOD_U and GOOD_L corresponding to the partial blocks PBLK_U and PBLK_L in the bad state are set to the “L” level.

### 1.2.2 Block Selection Operation

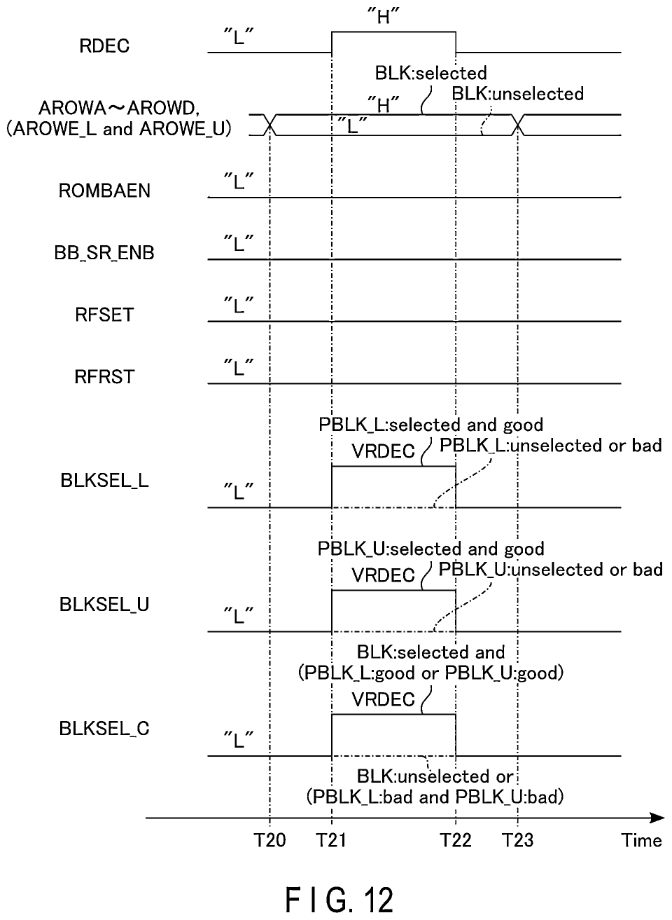

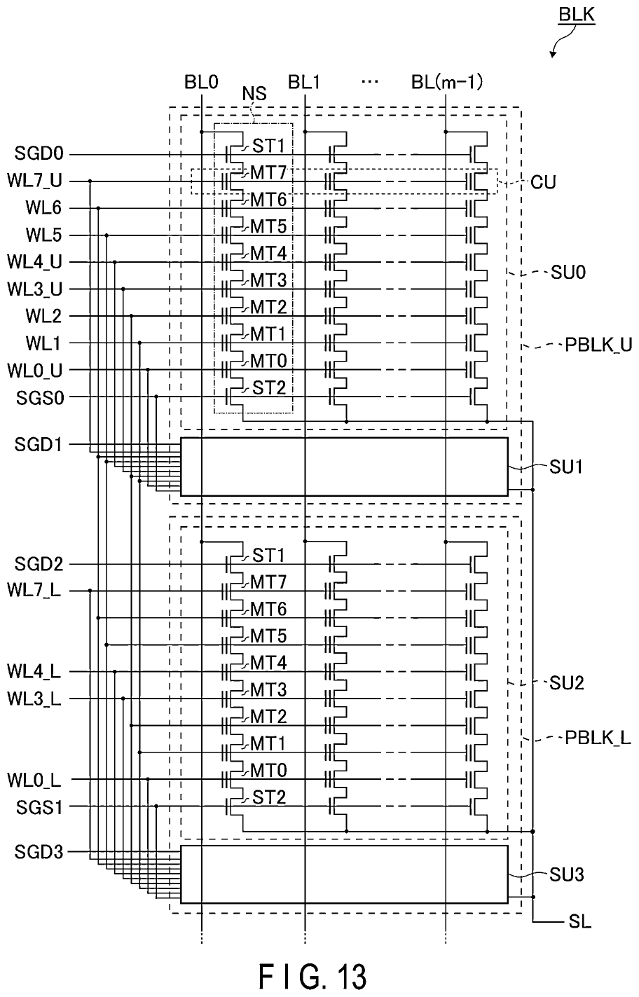

FIG. 12 is a timing chart illustrating an example of a block selection operation in the memory device according to the first embodiment.

At a time T20, the memory device 3 selects the block decoder BD corresponding to the block BLK to be selected. In other words, the memory device 3 selects the partial block PBLK in which the block address BAd is hit.

Specifically, the memory device 3 sets the logic levels of the nodes AROWA, AROWB, AROWC, AROWD, AROWE_U, and AROWE_L of the block decoders BD_U and BD_L corresponding to the block BLK that has hit the block address BAd to the “H” level. On the other hand, the memory device 3 sets the logic level of at least one node among the nodes AROWA, AROWB, AROWC, and AROWD, and the set of the nodes AROWE_U and AROWE_L of the block decoders BD_U and BD_L corresponding to the block BLK that has not hit the block address BAd to the “L” level.

In addition, the memory device 3 maintains the logical level of the node ROMBAEN at the “L” level. As a result, the transistors T28 and T48 go into an off state.

At a time T21, the memory device 3 changes the logic level of the node RDEC from the “L” level to the “H” level. As a result, the logical levels of the node RDEC_SEL_Un corresponding to the partial block PBLK_U in the good state and the block address BAd is hit, and the node RDEC_SEL_Ln corresponding to the partial block PBLK_L in the good state and the block address BAd is hit are changed from the “H” level to the “L” level. On the other hand, the logical level of the node RDEC_SEL_Un corresponding to the partial block PBLK_U in the bad state or the block address BAd is not hit, and the node RDEC_SEL_Ln corresponding to the partial block PBLK_L in the bad state or the block address BAd is not hit become the “L” level. Note that the initial setting value (that is, the logical level before time T20) of the nodes RDEC_SEL_Ln and RDEC_SEL_Un is at the “H” level.

In addition, the memory device 3 maintains the logical level of the node BB_SR_ENB at the “L” level. As a result, the logical levels of the node BLKSEL_U corresponding to the partial block PBLK_U in the good state and the block address BAd is hit, and the node BLKSEL_L corresponding to the partial block PBLK_L in the good state and the block address BAd is hit are changed from the “L” level to the “H” level. On the other hand, the logical levels of the node BLKSEL_U corresponding to the partial block PBLK_U in the bad state or the block address BAd does not hit, and the node BLKSEL_L corresponding to the partial block PBLK_L in the bad state or the block address BAd does not hit, are maintained at the “L” level. Then, in a case where the block address BAd is hit and at least one of the partial blocks PBLK_U and PBLK_L is in the good state, the logic level of the node BLKSEL_C becomes the “H” level. In a case where the block address BAd is not hit, or in a case where both the partial blocks PBLK_U and PBLK_L are in the bad state, the logic level of the node BLKSEL_C becomes the “L” level.

Therefore, among the blocks BLK to be selected, the partial block PBLK in the good state goes into a selected state, and the partial block PBLK in the bad state goes into a unselected state. That is, among the blocks BLK to be selected, the select gate lines SGD and SGS corresponding to the partial blocks PBLK in the good state are connected to the wirings SGDD and SGSD, respectively. Of the block BLK to be selected, the select gate lines SGD and SGS corresponding to the partial block PBLK in the bad state are connected to the wirings USGD and USGS, respectively. The word lines WL0 to WL7 corresponding to the block BLK to be selected are connected to the wirings CG0 to CG7 regardless of whether they are in the bad state or the good state. At this time, in the partial block PBLK in the bad state, since the select transistors ST1 and ST2 are in the off state, the memory cell transistor MT is in a floating state. Therefore, the partial block PBLK in the bad state goes into a unselected state.

At a time T22, the memory device 3 changes the logic level of the node RDEC from the “H” level to the “L” level.

At a time T23, the memory device 3 changes the logic levels of the nodes AROWA, AORWB, AROWC, AROWD, AROWE_U, and AROWE_L from the “H” level to the “L” level. As described above, the operation of selecting the block BLK ends.

### 1.3 Effects According to the First Embodiment

In the first embodiment, one block BLK is provided separately in two memory chips MC_U and MC_L. In this case, one of the partial block PBLK_U provided in the memory chip MC_U and the partial block PBLK_L provided in the memory chip MC_L may be in a good state, and the other may be in a bad state. If the partial block PBLK in the good state in the same block BLK as the partial block PBLK in the bad state cannot be used due to the partial block PBLK in the bad state, the use efficiency of the memory cell array 10 decreases. In addition, the amount of increase in the circuit area due to the formation of the block BLK serving as a spare increases.

According to the first embodiment, the block decoder BD_U switches the states of the select gate lines SGD0 and SGD1 of the partial block PBLK_U and the transfer switch WLSW_U connected to the SGS0. The block decoder BD_L switches the states of the select gate lines SGD2 and SGD3 of the partial block PBLK_L and the transfer switch WLSW_L connected to the SGS1. The block decoder BD_C switches the state of the transfer switch WLSW_C connected to the word lines WL0 to WL7 common to the partial blocks PBLK_U and PBLK_L. The block decoder BD_U supplies a common signal to the gates of the transistors TR8 to TR10 in the transfer switch WLSW_U through the node BLKSEL_U. The block decoder BD_L supplies a common signal different from the signal of the node BLKSEL_U to the gates of the transistors TR14 to TR16 in the transfer switch WLSW_L through the node BLKSEL_L. Accordingly, each of the block decoders BD_U and BD_L can independently switch the state of the transfer switch WLSW_U and the state of WLSW_L. Therefore, the row decoder module 15 can independently control the partial block PBLK_U and the partial block PBLK_L in the same block BLK. Therefore, an increase in the circuit area of the memory cell array 10 can be suppressed, and the use efficiency can be improved.

Further, the block decoders BD_U and BD_L include partial bad block latches PBBL_U and PBBL_L, respectively. As a result, partial bad block information corresponding to the number of memory chips MC can be stored in the row decoder RD corresponding to one block BLK. Therefore, the row decoder RD can operate so as not to use the partial block PBLK in the bad state while using the partial block PBLK in the good state.

In a case where the operation is performed such that the partial block PBLK in the bad state is not used while the partial block PBLK in the good state is used, the memory cell transistor MT of the partial block PBLK in the bad state is in a floating state. Therefore, the charging time of the word line WL is shortened so that it is possible to shorten the time required for the operation of applying the predetermined voltage to the word line WL, such as the write operation and the read operation, as compared with the case of simultaneously selecting the two partial blocks PBLK.

### 2. Second Embodiment

Next, a second embodiment will be described.

The second embodiment is different from the first embodiment in that some of the word lines WL0 to WL7 are connected to the block decoder BD_U or BD_L. Hereinafter, configurations and operations different from those of the first embodiment will be mainly described. Description of configurations and operations equivalent to those of the first embodiment will be omitted as appropriate.

### 2.1 Memory Cell Array

FIG. 13 is a plan view illustrating an example of a circuit configuration of a memory cell array according to the second embodiment. FIG. 13 corresponds to FIG. 2 in the first embodiment.

As shown in FIG. 13, in the same block BLK, control gates of memory cell transistors MT1, MT2, MT5, and MT6 are connected to word lines WL1, WL2, WL5, and WL6, respectively. Control gates of memory cell transistors MT0, MT3, MT4, and MT7 in string units SU0 and SU1 belonging to a partial block PBLK_U are connected to word lines WL0_U, WL3_U, WL4_U, and WL7_U, respectively. The control gates of the memory cell transistors MT0, MT3, MT4, and MT7 in string units SU2 and SU3 belonging to the partial block PBLK_L are connected to word lines WL0_L, WL3_L, WL4_L, and WL7_L, respectively.

Gates of the select transistors ST1 in the string units SU0 to SU3 are connected to select gate lines SGD0 to SGD3, respectively. Gates of the select transistors ST2 in the string units SU0 and SU1 are connected to a select gate line SGS0. Gates of the select transistors ST2 in the string units SU2 and SU3 are connected to a select gate line SGS1.

### 2.2 Row Decoder Module

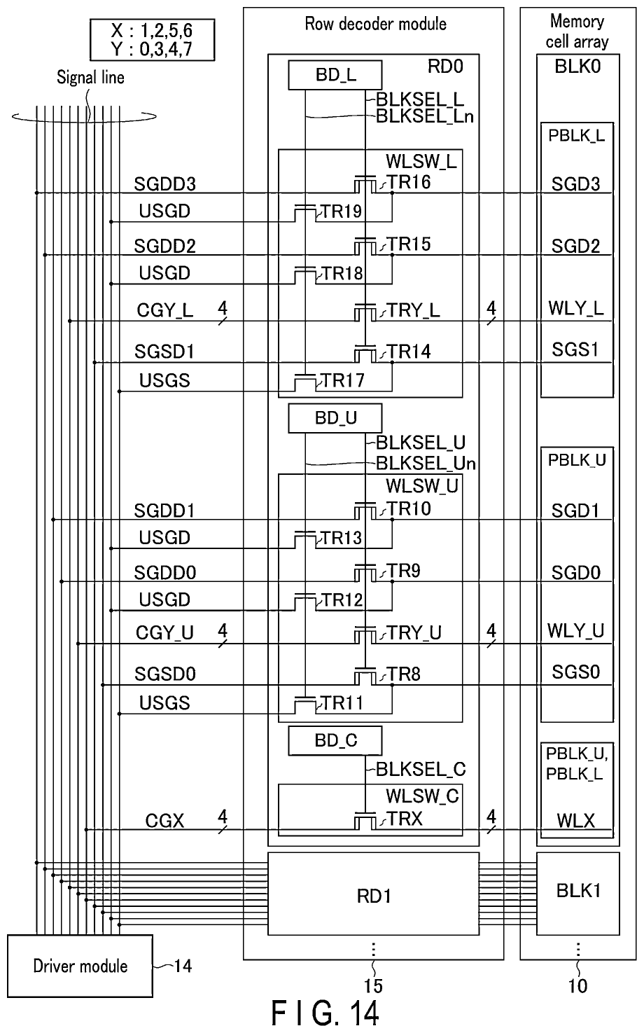

FIG. 14 is a circuit diagram illustrating an example of connection among a memory cell array, a row decoder module, and a driver module according to the second embodiment. FIG. 14 corresponds to FIG. 3 in the first embodiment.

As illustrated in FIG. 14, the transfer switch WLSW_C includes transistors TR1, TR2, TR5, and TR6. The transfer switch WLSW_U includes transistors TR0_U, TR3_U, TR4_U, TR7_U, and TR8 to TR13. The transfer switch WLSW_L includes transistors TR0_L, TR3_L, TR4_L, TR7_L, and TR14 to TR19. The configurations of block decoders BD_C, BD_U, and BD_L are the same as those of the first embodiment.

In FIG. 14, the word lines WL1, WL2, WL5, and WL6 are simplified like the word line WLX (X=1, 2, 5, and 6). Similarly, the transistors TR1, TR2, TR5, and TR6 and the wirings CG1, CG2, CG5, and CG6 are simplified like the transistor TRX and the wiring CGX, respectively. In FIG. 14, the word lines WL0_U, WL3_U, WL4_U, and WL7_U are simplified as the word line WLY_U, and the word lines WL0_L, WL3_L, WL4_L, and WL7_L are simplified as the word line WLY_L (Y=0, 3, 4, and 7). Similarly, the transistors TR0_U, TR3_U, TR4_U, and TR7_U, and the wirings CG0_U, CG3_U, CG4_U, and CG7_U are simplified as the transistor TRY_U and the wiring CGY_U, respectively. The transistors TR0_L, TR3_L, TR4_L, and TR7_L, and the wirings CG0_L, CG3_L, CG4_L, and CG7_L are simplified as the transistor TRY L and the wiring CGY_L, respectively.

The configurations of the transistors TR1, TR2, TR5, and TR6 in the transfer switch WLSW_C, the transistors TR8 to TR13 in the transfer switch WLSW_U, and the transistors TR14 to TR19 in the transfer switch WLSW_L are the same as those in the first embodiment.

Each of the transistors TR0_U, TR3_U, TR4_U, and TR7_U in the transfer switch WLSW_U is, for example, a high withstand voltage N-type transistor. First ends of the transistors TR0_U, TR3_U, TR4_U, and TR7_U are connected to the partial block PBLK_U of the block BLK0 through the word lines WL0_U, WL3_U, WL4_U, and WL7_U, respectively. Second ends of the transistors TR0_U, TR3_U, TR4_U, and TR7_U are connected to the driver module 14 through the wirings CG0_U, CG3_U, CG4_U, and CG7_U, respectively. Gates of the transistors TR0_U, TR3_U, TR4_U, and TR7_U are connected to the block decoder BD_U through the node BLKSEL_U.

Each of the transistors TR0_L, TR3_L, TR4_L, and TR7_L in the transfer switch WLSW_L is, for example, a high withstand voltage N-type transistor. The first ends of the transistors TR0_L, TR3_L, TR4_L, and TR7_L are connected to the partial block PBLK_L of the block BLK0 through the word lines WL0_L, WL3_L, WL4_L, and WL7_L, respectively. The second ends of the transistors TR0_L, TR3_L, TR4_L, and TR7_L are connected to the driver module 14 through the wirings CG0_L, CG3_L, CG4_L, and CG7_L, respectively. The gates of the transistors TR0_L, TR3_L, TR4_L, and TR7_L are connected to the block decoder BD_L through the node BLKSEL_L.

### 2.3 Cross-Sectional Structure of Memory Device

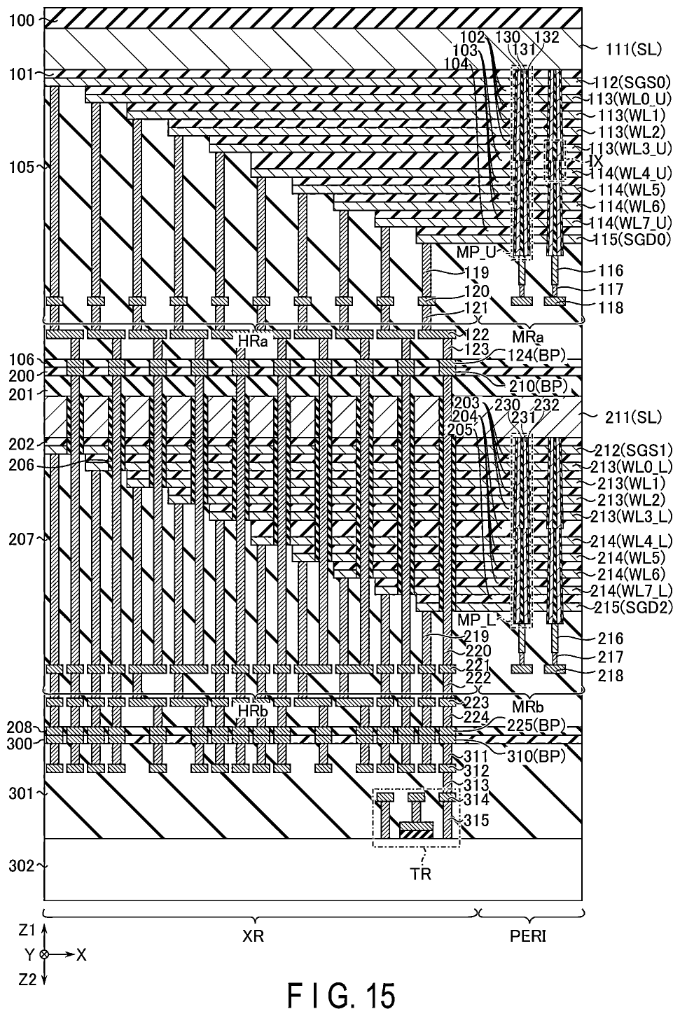

FIG. 15 is a cross-sectional view illustrating an example of a cross-sectional structure of a memory device according to the second embodiment. FIG. 15 corresponds to FIG. 8 in the first embodiment.

In the hookup region HRb of the memory chip MC_L, the plurality of conductor layers 221 is provided corresponding to the select gate lines SGS0 and SGS1, the word lines WL0_U, WL0_L, WL3_U, WL3_L, WL4_U, WL4_L, WL7_U, WL7_L, WL1, WL2, WL5, and WL6, and the select gate lines SGD0 to SGD3, respectively. That is, the number of the plurality of conductor layers 221 is eighteen. On the other hand, the number of the plurality of conductors 219 is eleven corresponding to the select gate line SGS1, the word lines WL0_L, WL1, WL2, WL3_L, WL4_L, WL5, WL6, and WL7_L provided in the memory chip MC_L, and the select gate lines SGD2 and SGD3. The number of the plurality of conductors 220 is eleven corresponding to the select gate line SGS0, the word lines WL0_U, WL1, WL2, WL3_U, WL4_U, WL5, WL6, and WL7_U provided in the memory chip MC_U, and the select gate lines SGD0 and SGD1. In the example of FIG. 15, the conductor 220 and the conductor layer 221 corresponding to the select gate line SGD1, and the conductor 219 and the conductor layer 221 corresponding to the select gate line SGD3 are not illustrated.

In the second embodiment, the conductor 219 and the conductor 220 corresponding to the same word line WL are connected to one conductor layer 221 for each of the word lines WL1, WL2, WL5, and WL6. The seven conductors 219 corresponding to the word lines WL0_L, WL3_L, WL4_L, and WL7_L and the select gate lines SGS1, SGD2, and SGD3 and the seven conductors 220 corresponding to the word lines WL0_U, WL3_U, WL4_U, and WL7_U and the select gate lines SGS0, SGD0, and SGD1 are connected to fourteen conductor layers 221 different from each other. These eighteen conductor layers 221 are electrically insulated from each other.

### 2.3 Effects According to Second Embodiment

The characteristics of the memory cell transistor MT provided at the end portion of the memory pillar MP may be deteriorated more than those of the memory cell transistor MT provided at the center. In this case, the memory cell transistor MT provided at the end portion of the memory pillar MP is more likely to cause a defect such as short circuit or open of the word line WL than the memory cell transistor MT provided at the center. On the other hand, in the same block BLK, the word line WL is shared between the memory chips MC_U and MC_L. Therefore, due to a failure occurring in the memory cell transistor MT at the end portion of the memory pillar MP of one of the memory chips MC_U and MC_L, the entire block BLK including the memory pillar MP may become unusable.

According to the second embodiment, the block decoder BD_U switches the states of the transfer switches WLSW_U connected to the select gate lines SGD0, SGD1, and SGS0 of the partial block PBLK_U and the word lines WL0_U and WL7_U. The block decoder BD_L switches the state of the transfer switch WLSW_L connected to the select gate lines SGD2, SGD3, and SGS1 of the partial block PBLK_L and the word lines WL0_L and WL7_L. The block decoder BD_U supplies a common signal to the gates of the transistors TR0_U, TR7_U, and TR8 to TR10 in the transfer switch WLSW_U through the node BLKSEL_U. The block decoder BD_L supplies a common signal different from the signal of the node BLKSEL_U to the gates of the transistors TR0_L, TR7_L, and TR14 to TR16 in the transfer switch WLSW_L through the node BLKSEL_L. As a result, even in a case where a failure occurs in the memory cell transistor MT at the end portion of the memory pillar MP, the row decoder module 15 can independently control the partial block PBLK_U and the partial block PBLK_L in the same block BLK. Therefore, an increase in the circuit area of the memory cell array 10 can be suppressed, and the use efficiency can be improved.

In addition, the memory pillar MP may be configured to have an upper portion TIER1 and a lower portion TIER2. In this case, the failure is also likely to occur in the memory cell transistor MT in a junction portion (that is, an end portion on the lower portion TIER2 side among both ends of the upper portion TIER1 and an end portion on the upper portion TIER1 side among both ends of the lower portion TIER2) of the upper portion TIER1 and the lower portion TIER2.

According to the second embodiment, the block decoder BD_U further switches the state of the transfer switch WLSW_U connected to the word lines WL3_U and WL4_U of the partial block PBLK_U. The block decoder BD_L further switches the state of the transfer switch WLSW_L connected to the word lines WL3_L and WL4_L of the partial block PBLK_L. The block decoder BD_U also supplies a common signal to the gates of the transistors TR3_U and TR4_U in the transfer switch WLSW_U through the node BLKSEL_U. The block decoder BD_L also supplies a common signal different from the signal of the node BLKSEL_U to the gates of the transistors TR3_L and TR4_L in the transfer switch WLSW_L through the node BLKSEL_L. As a result, the row decoder module 15 can independently control the partial block PBLK_U and the partial block PBLK_L in the same block BLK even in a case where a failure occurs in the memory cell transistor MT at the junction portion between the upper portion TIER1 and the lower portion TIER2 of the memory pillar MP. Therefore, an increase in the circuit area of the memory cell array 10 can be suppressed, and the use efficiency can be improved.

### 3. Third Embodiment

Next, a third embodiment will be described.

The third embodiment is different from the first embodiment and the second embodiment in that there are a plurality of blocks BLK corresponding to one block decoder BD. Hereinafter, configurations and operations different from those of the first embodiment will be mainly described. Description of configurations and operations equivalent to those of the first embodiment will be omitted as appropriate.

### 3.1 Memory Cell Array

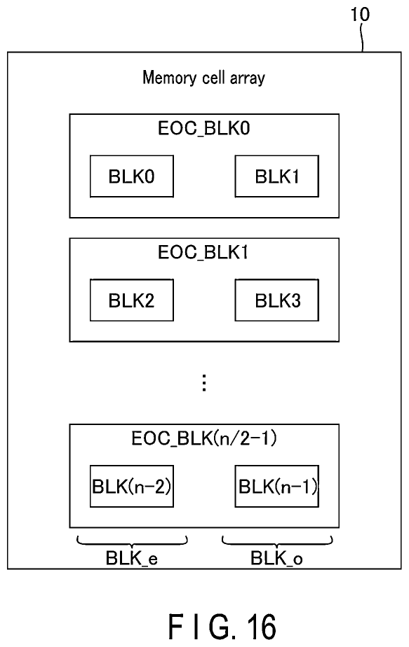

FIG. 16 is a block diagram illustrating an example of a configuration of a memory cell array according to the third embodiment.

As illustrated in FIG. 16, a memory cell array 10 includes a plurality of block sets EOC_BLK (EOC_BLK0, EOC_BLK1, . . . , and EOC_BLK (n/2−1)) (n is an even number). Each of the plurality of block sets EOC_BLK includes two blocks BLK.

In the example of FIG. 16, the block set EOC_BLK0 includes blocks BLK0 and BLK1. The block set EOC_BLK1 includes blocks BLK2 and BLK3. The block set EOC_BLK (n/2−1) includes blocks BLK (n−2) and BLK (n−1).

Hereinafter, among the blocks BLK included in each of the plurality of block sets EOC_BLK, the blocks BLK0, BLK2, . . . and BLK (n−2) having an even number at the end are also collectively referred to as a block BLK_e. Among the blocks BLK included in each of the plurality of block sets EOC_BLK, the blocks BLK1, BLK3, . . . , and BLK (n−1) having an odd number at the end are also collectively referred to as a block BLK_o. In addition, “_e” and “_o” may be added to the end of the reference numerals indicating the configurations corresponding to the blocks BLK_e and BLK_o, respectively.

### 3.2 Row Decoder Module

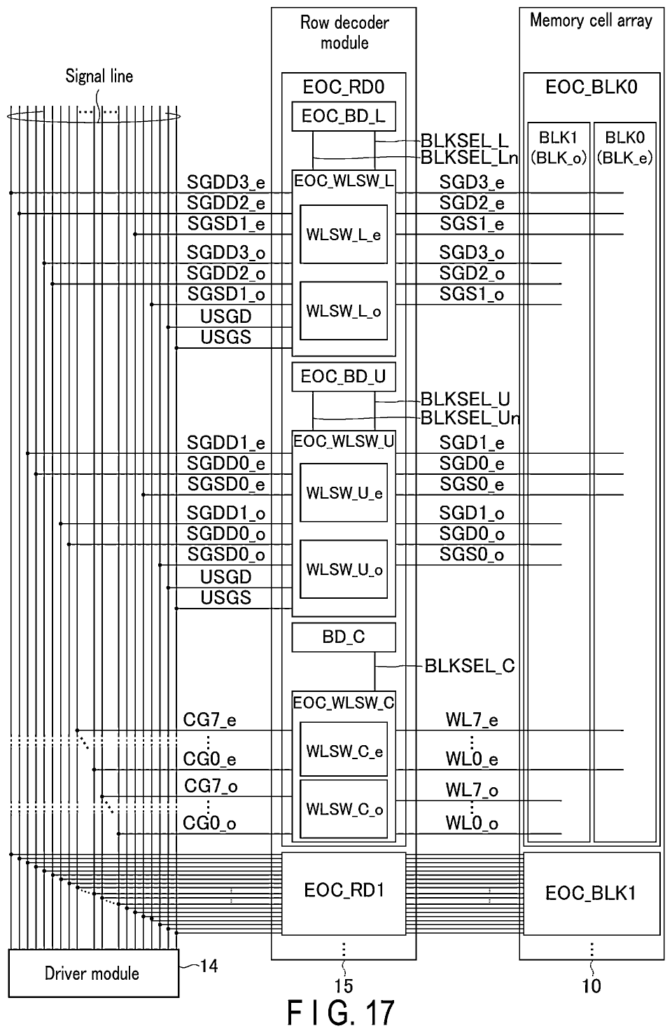

FIG. 17 is a circuit diagram illustrating an example of connection among a memory cell array, a row decoder module, and a driver module according to the third embodiment. FIG. 17 corresponds to FIG. 3 in the first embodiment. As illustrated in FIG. 17, a row decoder module 15 includes a plurality of row decoder sets EOC_RD (EOC_RD0, EOC_RD1, . . . ). The number of row decoder sets EOC_RD corresponds to the number of block sets EOC_BLK. Each of the plurality of row decoder sets EOC_RD has an equivalent configuration. In the example of FIG. 17, the configuration of the row decoder set EOC_RD0 corresponding to the block set EOC_BLK0 is illustrated. The row decoder set EOC_RD0 includes a block decoder BD_C, block decoder sets EOC_BD_U and EOC_BD_L, and transfer switch sets EOC_WLSW_C, EOC_WLSW_U, and EOC_WLSW_L.

### 3.2.1 Transfer Switch

First, the configurations of the transfer switch sets EOC_WLSW_C, EOC_WLSW_U, and EOC_WLSW_L will be described with reference to FIG. 17.

The transfer switch set EOC_WLSW_C includes transfer switches WLSW_C_e and WLSW_C_o. The configurations of the transfer switches WLSW_C_e and WLSW_C_o are the same as the configuration of the transfer switch WLSW_C in the first embodiment except that the transfer switches WLSW_C_e and WLSW_C_o are connected to the block decoder BD_C through the common node BLKSEL_C. That is, although not illustrated in FIG. 17, the transistors TR0 to TR7 in the transfer switch WLSW_C_e, respectively, have first ends connected to the block BLK_e through the word lines WL0_e to WL7_e, second ends connected to the driver module 14 through the wirings CG0_e to CG7_e, and gates connected to the block decoder BD_C through the node BLKSEL_C. The transistors TR0 to TR7 in the transfer switch WLSW_C_o, respectively, have first ends connected to the block BLK_o through the word lines WL0_o to WL7_o, second ends connected to the driver module 14 through the wirings CG0_o to CG7_o, and gates connected to the block decoder BD_C through the node BLKSEL_C.

The transfer switch set EOC_WLSW_U includes transfer switches WLSW_U_e and WLSW_U_o. The configurations of the transfer switches WLSW_U_e and WLSW_U_o are equivalent to the configuration of the transfer switch WLSW_U in the first embodiment except that the transfer switches are connected to the block decoder set EOC_BD_U through the common nodes BLKSEL_U and BLKSEL_Un. That is, although not illustrated in FIG. 17, each of the transistors TR8 to TR10 in the transfer switch WLSW_U_e, respectively, have first ends connected to the block BLK_e through the select gate lines SGS0_e, SGD0_e, and SGD1_e, second ends connected to the driver module 14 through the wirings SGSD0_e, SGDD0_e, and SGDD1_e, and gates connected to the block decoder set EOC_BD_U through the node BLKSEL_U. The transistors TR11 to TR13 in the transfer switch WLSW_U_e, respectively, have first ends connected to the block BLK_e through the select gate lines SGS0_e, SGD0_e, and SGD1_e, second ends connected to the driver module 14 through the wirings USGS, USGD, and USGD, and gates connected to the block decoder set EOC_BD_U through the node BLKSEL_Un. The transistors TR8 to TR10 in the transfer switch WLSW_U_o, respectively, have first ends connected to the block BLK_o through the select gate lines SGS0_o, SGD0_o, and SGD1_o, second ends connected to the driver module 14 through the wirings SGSD0_o, SGDD0_o, and SGDD1_o, and gates connected to the block decoder set EOC_BD_U through the node BLKSEL_U. The transistors TR11 to TR13 in the transfer switch WLSW_U_o, respectively, have first ends connected to the block BLK_o through the select gate lines SGS0_o, SGD0_o, and SGD1_o, second ends connected to the driver module 14 through the wirings USGS, USGD, and USGD, and gates connected to the block decoder set EOC_BD_U through the node BLKSEL_Un.

The transfer switch set EOC_WLSW_L includes transfer switches WLSW_L_e and WLSW_L_o. The configurations of the transfer switches WLSW_L_e and WLSW_L_o are equivalent to the configuration of the transfer switch WLSW_L in the first embodiment except that the transfer switches are connected to the block decoder set EOC_BD_L through the common nodes BLKSEL_L and BLKSEL_Ln. That is, although not illustrated in FIG. 17, each of the transistors TR14 to TR16 in the transfer switch WLSW_L_e, respectively, have first ends connected to the block BLK_e through the select gate lines SGS1_e, SGD2_e, and SGD3_e, second ends connected to the driver module 14 through the wirings SGSD1_e, SGDD2_e, and SGDD3_e, and gates connected to the block decoder set EOC_BD_L through the node BLKSEL_L. The transistors TR17 to TR19 in the transfer switch WLSW_L_e, respectively, have first ends connected to the block BLK_e through the select gate lines SGS1_e, SGD2_e, and SGD3_e, second ends connected to the driver module 14 through the wirings USGS, USGD, and USGD, and gates connected to the block decoder set EOC_BD_L through the node BLKSEL_Ln. The transistors TR14 to TR16 in the transfer switch WLSW_L_o, respectively, have first ends connected to the block BLK_o through the select gate lines SGS1_o, SGD2_o, and SGD3_o, second ends connected to the driver module 14 through the wirings SGSD1_o, SGDD2_o, and SGDD3_o, and gates connected to the block decoder set EOC_BD_L through the node BLKSEL_L. The transistors TR17 to TR19 in the transfer switch WLSW_L_o, respectively, have first ends connected to the block BLK_o through the select gate lines SGS1_o, SGD2_o, and SGD3_o, second ends connected to the driver module 14 through the wirings USGS, USGD, and USGD, and gates connected to the block decoder set EOC_BD_L through the node BLKSEL_Ln.

### 3.2.2 Block Decoder

Next, the configurations of the block decoder sets EOC_BD_U and EOC_BD_L will be described.

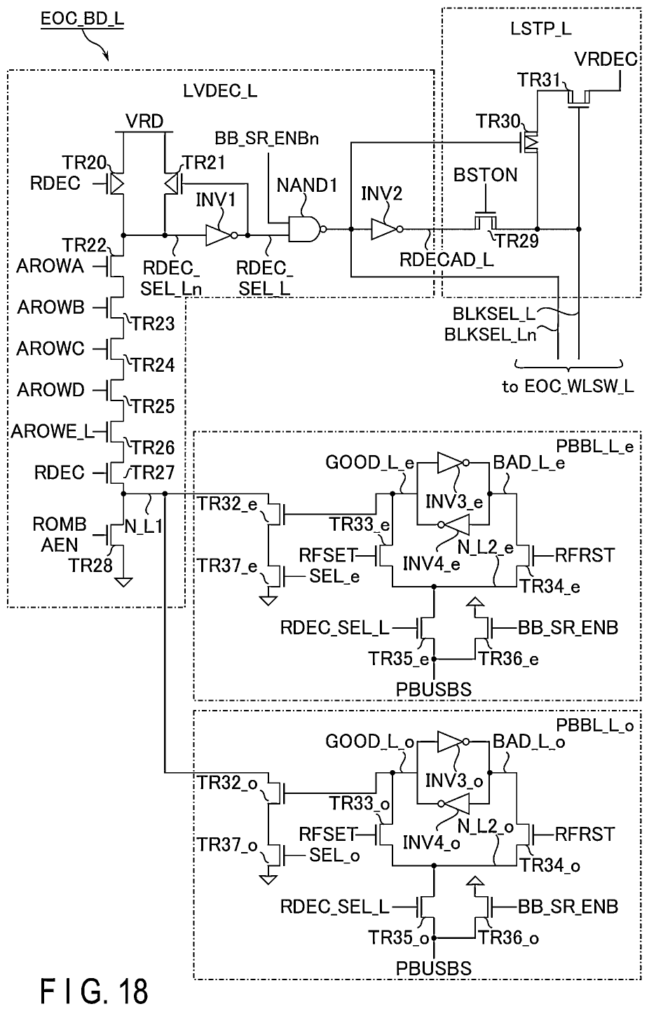

FIG. 18 is a circuit diagram illustrating an example of a configuration of a first portion of a block decoder set according to the third embodiment. The first portion of the block decoder set corresponds to the block decoder set EOC_BD_L. As illustrated in FIG. 18, the block decoder set EOC_BD_L includes a decoder LVDEC_L, a level shifter LSTP_L, and partial bad block latches PBBL_L_e and PBBL_L_o.

The configurations of the decoder LVDEC_L and the level shifter LSTP_L are equivalent to the configurations of the decoder LVDEC_L and the level shifter LSTP_L in the first embodiment.

The partial bad block latches PBBL_L_e and PBBL_L_o have the same configuration and are connected in parallel to the node N_L1.

Specifically, the partial bad block latch PBBL_L_e includes transistors TR32_e, TR33_e, TR34_e, TR35_e, TR36_e, and TR37_e, and inverters INV3_e and INV4_e. The transistors TR32_e to TR37_e are, for example, N-type transistors.

The transistor TR32_e has a first end connected to the node N_L1 and a gate connected to a node GOOD_L_e. The transistor TR33_e has a first end connected to the node GOOD_L_e, a second end connected to a node N_L2_e, and a gate connected to the node RFSET. The transistor TR34_e has a first end connected to a node BAD_L_e, a second end connected to the node N_L2_e, and a gate connected to the node RFRST.

The transistor TR35_e has a first end connected to the node N_L2_e, a second end connected to the node PBUSBS, and a gate connected to the node RDEC_SEL_L. The transistor TR36_e has a first end connected to the node PBUSBS, a second end grounded, and a gate connected to the node BB_SR_ENB.

The transistor TR37_e has a first end connected to a second end of the transistor TR32_e, a second end grounded, and a gate connected to a node SEL_e.

The inverter INV3_e has an input terminal connected to the node GOOD_L_e and an output terminal connected to the node BAD_L_e. That is, the inverter INV3_e inverts the logic level of the node GOOD_L_e and outputs the inverted logic level to the node BAD_L_e. The inverter INV4_e has an input end connected to the node BAD_L_e and an output end connected to the node GOOD_L_e. That is, the inverter INV4_e inverts the logic level of the node BAD_L_e and outputs the inverted logic level to the node GOOD_L_e.

Similarly, the partial bad block latch PBBL_L_o includes transistors TR32_o, TR33_o, TR34_o, TR35_o, TR36_o, and TR37_o, and inverters INV3_o and INV4_o. The transistors TR32_o to TR37_o are, for example, N-type transistors.

The transistor TR32_o has a first end connected to the node N_L1 and a gate connected to a node GOOD_L_o. The transistor TR33_o has a first end connected to the node GOOD_L_o, a second end connected to a node N_12_o, and a gate connected to the node RFSET. The transistor TR34_o has a first end connected to a node BAD_L_o, a second end connected to the node N_L2_o, and a gate connected to the node RFRST.

The transistor TR35_o has a first end connected to the node N_L2_o, a second end connected to the node PBUSBS, and a gate connected to the node RDEC_SEL_L. The transistor TR36_o has a first end connected to the node PBUSBS, a second end grounded, and a gate connected to the node BB_SR_ENB.

The transistor TR37_o has a first end connected to a second end of the transistor TR32_o, a second end grounded, and a gate connected to a node SEL_o.

The inverter INV3_o has an input end connected to the node GOOD_L_o and an output end connected to the node BAD_L_o. That is, the inverter INV3_o inverts the logic level of the node GOOD_L_o and outputs the inverted logic level to the node BAD_L_o. The inverter INV4_o has an input end connected to the node BAD_L_o and an output end connected to the node GOOD_L_o. That is, the inverter INV4_o inverts the logic level of the node BAD_L_o and outputs the inverted logic level to the node GOOD_L_o.

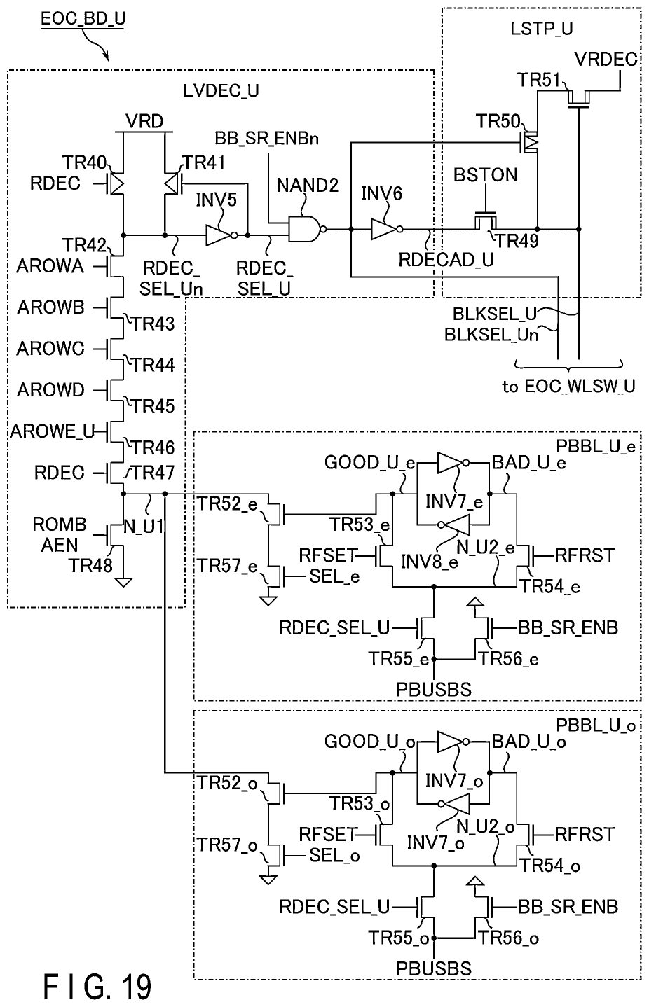

FIG. 19 is a circuit diagram illustrating an example of a configuration of the second portion of the block decoder set according to the third embodiment. The second portion of the block decoder set corresponds to the block decoder set EOC_BD_U. As illustrated in FIG. 19, the block decoder set EOC_BD_U includes a decoder LVDEC_U, a level shifter LSTP_U, and partial bad block latches PBBL_U_e and PBBL_U_O.

The configurations of the decoder LVDEC_U and the level shifter LSTP_U are equivalent to the configurations of the decoder LVDEC_U and the level shifter LSTP_U in the first embodiment.

The partial bad block latches PBBL_U_e and PBBL_U_o have the same configuration and are connected in parallel to a node N_U1.

Specifically, the partial bad block latch PBBL_U_e includes transistors TR52_e, TR53_e, TR54_e, TR55_e, TR56_e, and TR57_e, and inverters INV7_e and INV8_e. The transistors TR52_e to TR57_e are, for example, N-type transistors.

The transistor TR52_e has a first end connected to the node N_U1 and a gate connected to a node GOOD_U_e. The transistor TR53_e has a first end connected to the node GOOD_U_e, a second end connected to a node N_U2_e, and a gate connected to the node RFSET. The transistor TR54_e has a first end connected to a node BAD_U_e, a second end connected to a node N_U2_e, and a gate connected to the node RFRST.

The transistor TR55_e has a first end connected to the node N_U2_e, a second end connected to the node PBUSBS, and a gate connected to the node RDEC_SEL_U. The transistor TR56_e has a first end connected to the node PBUSBS, a second end grounded, and a gate connected to the node BB_SR_ENB.

The transistor TR57_e has a first end connected to a second end of the transistor TR52_e, a second end grounded, and a gate connected to the node SEL_e.

The inverter INV7_e has an input end connected to the node GOOD_U_e and an output end connected to the node BAD_U_e. That is, the inverter INV7_e inverts the logic level of the node GOOD_U_e and outputs the inverted logic level to the node BAD_U_e. The inverter INV8_e has an input end connected to the node BAD_U_e and an output end connected to the node GOOD_U_e. That is, the inverter INV8_e inverts the logic level of the node BAD_U_e and outputs the inverted logic level to the node GOOD_U_e.

Similarly, the partial bad block latch PBBL_U_O includes transistors TR52_o, TR53_o, TR54_o, TR55_o, TR56_o, and TR57_o, and inverters INV7_o and INV8_o. The transistors TR52_o to TR57_o are, for example, N-type transistors.

The transistor TR52_o has a first end connected to the node N_U1 and a gate connected to a node GOOD_U_o. The transistor TR53_o has a first end connected to the node GOOD_U_o, a second end connected to a node N_U2_o, and a gate connected to the node RFSET. The transistor TR54_o has a first end connected to a node BAD_U_o, a second end connected to the node N_U2_o, and a gate connected to the node RFRST.

The transistor TR55_o has a first end connected to the node N_U2_o, a second end connected to the node PBUSBS, and a gate connected to the node RDEC_SEL_U. The transistor TR56_o has a first end connected to the node PBUSBS, a second end grounded, and a gate connected to the node BB_SR_ENB.

The transistor TR57_o has a first end connected to a second end of the transistor TR52_o, a second end grounded, and a gate connected to the node SEL_o.

The inverter INV7_o has an input end connected to the node GOOD_U_o and an output end connected to the node BAD_U_o. That is, the inverter INV7_o inverts the logic level of the node GOOD_U_o and outputs the inverted logic level to the node BAD_U_o. The inverter INV8_o has an input end connected to the node BAD_U_o and an output end connected to the node GOOD_U_o. That is, the inverter INV8_o inverts the logic level of the node BAD_U_o and outputs the inverted logic level to the node GOOD_U_o.

### 3.3 Effects According to the Third Embodiment

According to the third embodiment, the block decoder set EOC_BD_U switches the states of the select gate lines SGD0_e and SGD1_e of the partial block PBLK_U in the block BLK_e and the transfer switches WLSW_U_e connected to SGS0_e, and switches the states of the select gate lines SGD0_o and SGD1_o of the partial block PBLK_U in the block BLK_o and the transfer switches WLSW_U_o connected to SGS0_o. The block decoder set EOC_BD_L switches the states of the select gate lines SGD2_e and SGD3_e of the partial block PBLK_L in the block BLK_e and the transfer switch WLSW_L connected to the SGS1_e, and switches the states of the select gate lines SGD2_o and SGD3_o of the partial block PBLK_L in the block BLK_o and the transfer switch WLSW_L_o connected to the SGS1_o. The block decoder BD_C switches the state of the transfer switch WLSW_C_e connected to the word lines WL0_e to WL7_e common to the partial blocks PBLK_U and PBLK_L in the block BLK_e, and switches the state of the transfer switch WLSW_C_o connected to the word lines WL0_o to WL7_o common to the partial blocks PBLK_U and PBLK_L in the block BLK_o. As a result, the row decoder set EOC_RD can control the two blocks BLK_e and BLK_o.

The block decoder set EOC_BD_U includes partial bad block latches PBBL_U_e and PBBL_U_o. The block decoder set EOC_BD_L includes partial bad block latches PBBL_L_e and PBBL_L_o. As a result, partial bad block information corresponding to the number of memory chips MC can be stored in the row decoder RD corresponding to one block BLK. Therefore, the row decoder set EOC_RD can operate so as to use the partial block PBLK in the good state and not to use the partial block PBLK in the bad state for each of the blocks BLK_e and BLK_o.

### 4. Fourth Embodiment

Next, a fourth embodiment will be described.

The fourth embodiment is different from the first, second, and third embodiments in that a configuration for storing partial bad block information is provided at a location different from that of the row decoder module 15. Hereinafter, configurations and operations different from those of the first embodiment will be mainly described. Description of configurations and operations equivalent to those of the first embodiment will be omitted as appropriate.

### 4.1 Block Decoder

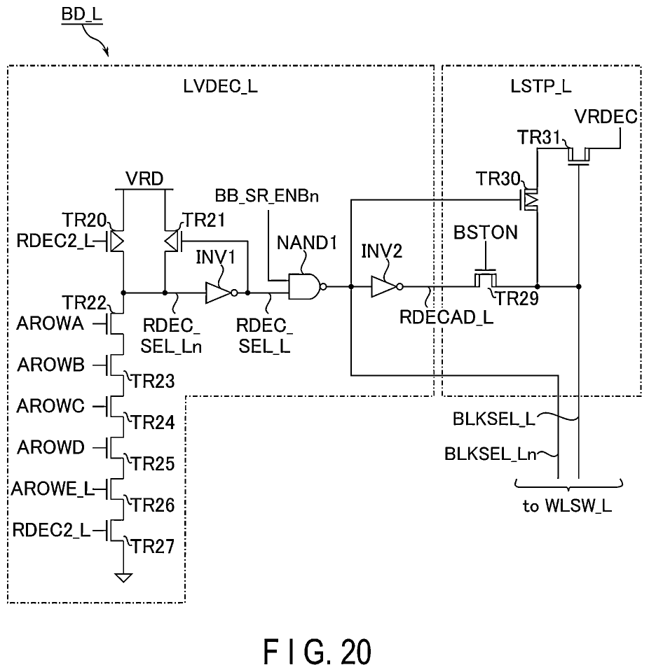

FIG. 20 is a circuit diagram illustrating an example of a configuration of a first portion of a block decoder according to the fourth embodiment. FIG. 20 corresponds to FIG. 4 in the first embodiment.

As illustrated in FIG. 20, a block decoder BD_L may not include the transistor TR28 in the decoder LVDEC_L and the partial bad block latch PBBL_L. In this case, gates of transistors TR20 and TR27 are connected to a node RDEC2_L. A logical level of the node RDEC2_L indicates whether or not the corresponding partial block PBLK_L is in a bad state.

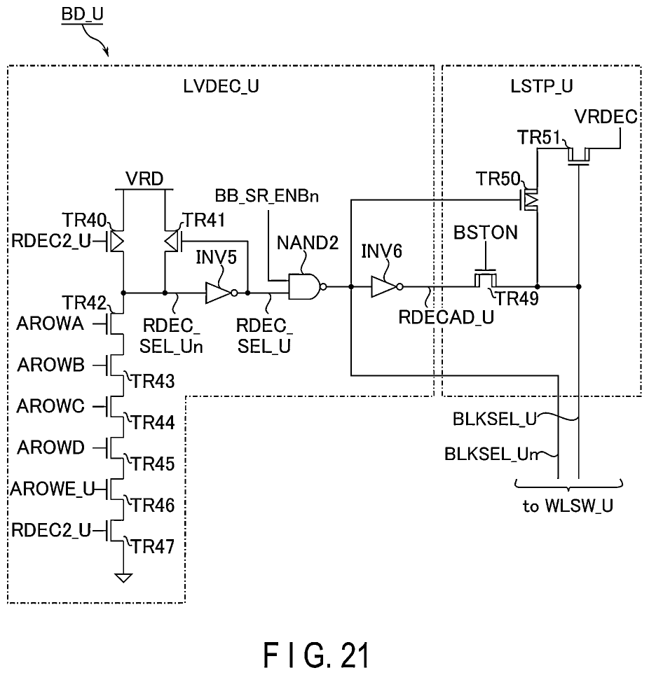

FIG. 21 is a circuit diagram illustrating an example of a configuration of the second portion of the block decoder according to the fourth embodiment. FIG. 21 corresponds to FIG. 5 in the first embodiment.

As illustrated in FIG. 21, a block decoder BD_U may not include the transistor TR48 and the partial bad block latch PBBL_U in the decoder LVDEC_U. In this case, gates of transistors TR40 and TR48 are connected to a node RDEC2_U. The logical level of the node RDEC2_U indicates whether or not the corresponding partial block PBLK_U is in the bad state.

As described above, block decoders BD_L and BD_U are provided in the transfer region XR. In a case where the block decoders BD_L and BD_U do not include partial bad block latches PBBL_L and PBBL_U, respectively, the configurations corresponding to the partial bad block latches PBBL_L and PBBL_U may not be provided in the transfer region XR. For example, configurations corresponding to the partial bad block latches PBBL_L and PBBL_U may be provided in a peripheral circuit region PERI.

Hereinafter, for convenience of description, the configurations corresponding to the partial bad block latches PBBL_L and PBBL_U are referred to as bad block information storage circuits.

### 4.2 Bad Block Information Storage Circuit

Next, a configuration of the bad block information storage circuit according to the fourth embodiment will be described. The bad block information storage circuit can be implemented by various configurations. Hereinafter, a first example and a second example of the configuration of a bad block information storage circuit BB will be described.

### 4.2.1 First Example

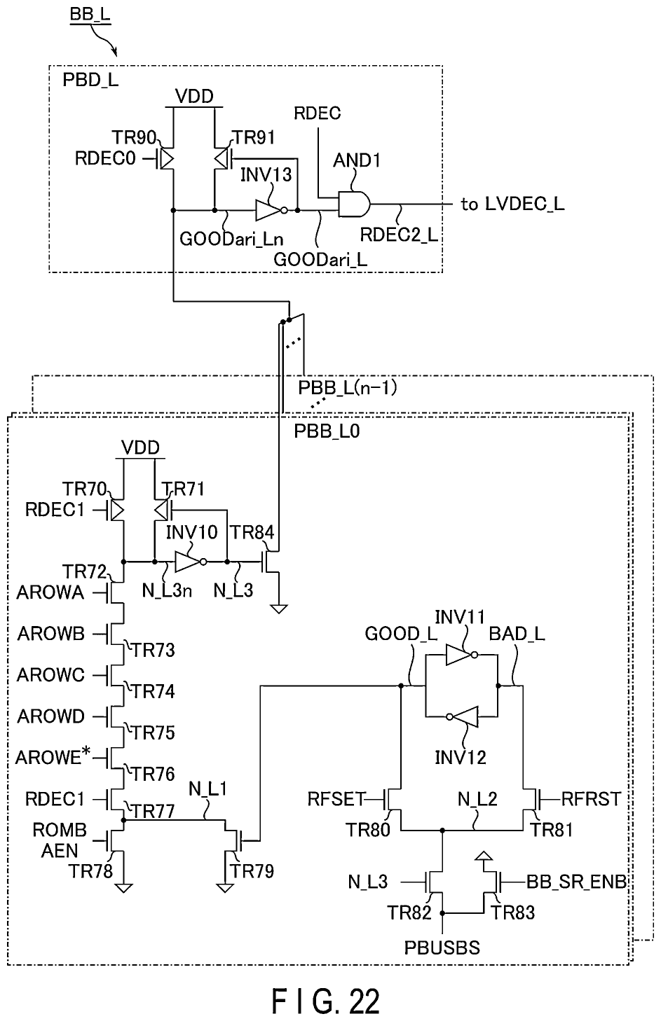

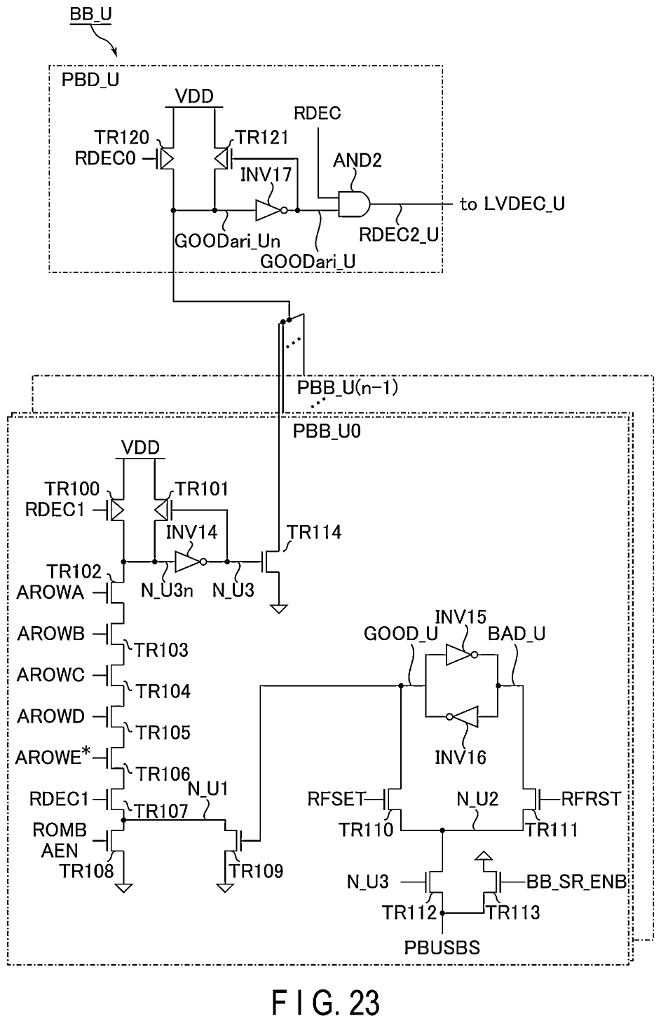

FIG. 22 is a circuit diagram illustrating a first example of the configuration of the first portion of the bad block information storage circuit according to the fourth embodiment. FIG. 23 is a circuit diagram illustrating a first example of the configuration of the second portion of the bad block information storage circuit according to the fourth embodiment. A first portion BB_L of the bad block information storage circuit is configured to be connected to the block decoder BD_L through the node RDEC2_L. A second portion BB_U of the bad block information storage circuit is configured to be connected to the block decoder BD_U through the node RDEC2_U.

First, the first portion BB_L of the bad block information storage circuit will be described.

As illustrated in FIG. 22, the first portion BB_L of the bad block information storage circuit may include a partial bad block latch. Specifically, the first portion BB_L of the bad block information storage circuit includes a decoder PBD_L and a plurality of partial bad block information storage circuits PBB_L (PBB_L0, . . . , and PBB_L (n−1)).

Each of the plurality of partial bad block information storage circuits PBB_L is connected in parallel to a node GOODari_Ln. Each of the plurality of partial bad block information storage circuits PBB_L0 to PBB_L (n−1) stores information indicating whether or not partial blocks PBLK0_L to PBLK (n−1) L are in the bad state. Each of the plurality of partial bad block information storage circuits PBB_L has the same configuration. Hereinafter, as an example, a configuration of the partial bad block information storage circuit PBB_L0 will be described.

The partial bad block information storage circuit PBB_L0 includes transistors TR70, TR71, TR72, TR73, TR74, TR75, TR76, TR77, TR78, TR79, TR80, TR81, TR82, TR83, and TR84, and inverters INV10, INV11, and INV12. The transistors TR70 and TR71 are, for example, P-type transistors. The transistors TR72 to TR84 are, for example, N-type transistors.

The transistor TR70 has a first end to which a voltage VDD is applied, a second end connected to a node N_L3n, and a gate connected to a node RDEC1. The transistor TR71 has a first end to which the voltage VDD is applied, a second end connected to the node N_L3n, and a gate connected to a node N_L3. The voltage VDD corresponds to, for example, a logic level of the “H” level in the first portion BB_L and the second portion BB_U of the bad block information storage circuit.

An inverter INV10 has an input terminal connected to the node N_L3n and an output terminal connected to the node N_L3. That is, the inverter INV10 inverts the logic level of the node N_L3n and outputs the inverted logic level to the node N_L3.

The transistor TR72 has a first end connected to the node N_L3n and a gate connected to the node AROWA. The transistor TR73 has a first end connected to a second end of the transistor TR72 and a gate connected to the node AROWB. The transistor TR74 has a first end connected to a second end of the transistor TR73 and a gate connected to the node AROWC. The transistor TR75 has a first end connected to a second end of the transistor TR74 and a gate connected to the node AROWD. The transistor TR76 has a first end connected to a second end of the transistor TR75 and a gate connected to a node AROWE*. The logic levels of the nodes AROWA to AROWE* connected to the partial bad block information storage circuit PBB_L are all at the “H” level in a case where the corresponding partial block PBLK_L is a selection target. At least one logical level among the logical levels of the nodes AROWA to AROWE* becomes the “L” level in a case where the corresponding partial block PBLK_L is not a selection target.

The transistor TR77 has a first end connected to a second end of the transistor TR76, a second end connected to the node N_L1, and a gate connected to the node RDEC1. The transistor TR78 has a first end connected to the node N_L1, a second end grounded, and a gate connected to the node ROMBAEN.

The transistor TR79 has a first end connected to the node N_L1, a second end grounded, and a gate connected to the node GOOD_L. The transistor TR80 has a first end connected to the node GOOD_L, a second end connected to the node N_L2, and a gate connected to the node RESET. The transistor TR81 has a first end connected to the node BAD_L, a second end connected to the node N_L2, and a gate connected to the node RFRST.

The transistor TR82 has a first end connected to the node N_L2, a second end connected to the node PBUSBS, and a gate connected to the node N_L3. The transistor TR83 has a first end connected to the node PBUSBS, a second end grounded, and a gate connected to the node BB_SR_ENB.

The inverter INV11 has an input end connected to a node GOOD_L and an output end connected to a node BAD_L. That is, the inverter INV11 inverts the logic level of the node GOOD_L and outputs the inverted logic level to the node BAD_L. The inverter INV12 has an input end connected to the node BAD_L and an output end connected to the node GOOD_L. That is, the inverter INV12 inverts the logic level of the node BAD_L and outputs the inverted logic level to the node GOOD_L.

The transistor TR84 has a first end connected to the node GOODari_Ln, a second end to be grounded, and a gate connected to the node N_L3.

The decoder PBD_L includes transistors TR90 and TR91, an inverter INV13, and a logic circuit AND1. The transistors TR90 and TR91 are, for example, P-type transistors.

The transistor TR90 includes a first end to which the voltage VDD is applied, a second end connected to the node GOODari_Ln, and a gate connected to a node RDEC0. The transistor TR91 has a first end to which the voltage VDD is applied, a second end connected to the node GOODari_Ln, and a gate connected to a node GOODari_L.

The inverter INV13 has an input terminal connected to the node GOODari_Ln and an output terminal connected to the node GOODari_L. That is, the inverter INV13 inverts the logic level of the node GOODari_Ln and outputs the inverted logic level to the node GOODari_L.

The logic circuit AND1 includes a first input terminal connected to the node GOODari_L, a second input terminal connected to the node RDEC, and an output terminal connected to the node RDEC2_L. That is, the logical circuit AND1 executes the logical AND operation of the logical level of the node GOODari_L and the logical level of the node RDEC, and outputs the execution result to the node RDEC2_L.

With the above configuration, whether the partial blocks PBLK_L0 to PBLK_L (n−1) are in the bad state or the good state is stored in each of the n partial bad block information storage circuits PBB_L0 to PBB_L (n−1). In a case where the partial block PBLK_L in the block BLK to be selected is in the bad state, the logical level of the node RDEC2_L is the “L” level. In a case where the partial block PBLK_L in the block BLK to be selected is in the good state, the logic level of the node RDEC2_L becomes the “H” level.

Next, the second portion BB_U of the bad block information storage circuit will be described.

As illustrated in FIG. 23, the second portion BB_U of the bad block information storage circuit may include a partial bad block latch similarly to the first portion BB_L. Specifically, the second portion BB_U of the bad block information storage circuit includes a decoder PBD_U and a plurality of partial bad block information storage circuits PBB_U (PBB_U0, . . . , and PBB_U (n−1)).

Each of the plurality of partial bad block information storage circuits PBB_U is connected in parallel to a node GOODari_Un. Each of the plurality of partial bad block information storage circuits PBB_U0 to PBB_U (n−1) stores information indicating whether or not the partial blocks PBLK0_U to PBLK (n−1) U are in the bad state. Each of the plurality of partial bad block information storage circuits PBB_U has an equivalent configuration. Hereinafter, as an example, a configuration of the partial bad block information storage circuit PBB_U0 will be described.

The partial bad block information storage circuit PBB_U0 includes transistors TR100, TR101, TR102, TR103, TR104, TR105, TR106, TR107, TR108, TR109, TR110, TR111, TR112, TR113, and TR114, and inverters INV14, INV15, and INV16. The transistors TR100 and TR101 are, for example, P-type transistors. The transistors TR102 to TR114 are, for example, N-type transistors.

The transistor TR100 has a first end to which the voltage VDD is applied, a second end connected to a N_U3n, and a gate connected to the node RDEC1. The transistor TR101 has a first end to which the voltage VDD is applied, a second end connected to the node N_U3n, and a gate connected to a node N_U3.

The inverter INV14 has an input end connected to the node N_U3n and an output end connected to the node N_U3. That is, the inverter INV14 inverts the logic level of the node N_U3n and outputs the inverted logic level to the node N_U3.

The transistor TR102 has a first end connected to the node N_U3n and a gate connected to the node AROWA. The transistor TR103 has a first end connected to a second end of the transistor TR102 and a gate connected to the node AROWB. The transistor TR104 has a first end connected to a second end of the transistor TR103 and a gate connected to the node AROWC. The transistor TR105 has a first end connected to a second end of the transistor TR104 and a gate connected to the node AROWD. The transistor TR106 has a first end connected to a second end of the transistor TR105 and a gate connected to the node AROWE*. The logic levels of the nodes AROWA to AROWE* connected to the partial bad block information storage circuit PBB_U are all at the “H” level in a case where the corresponding partial block PBLK_U is a selection target. At least one logical level among the logical levels of the nodes AROWA to AROWE* becomes the “L” level in a case where the corresponding partial block PBLK_U is not a selection target.

The transistor TR107 has a first end connected to a second end of the transistor TR106, a second end connected to a node N_U1, and a gate connected to the node RDEC1. The transistor TR108 has a first end connected to the node N_U1, a second end grounded, and a gate connected to the node ROMBAEN.

The transistor TR109 has a first end connected to the node N_U1, a second end grounded, and a gate connected to a node GOOD_U. The transistor TR110 has a first end connected to the node GOOD_U, a second end connected to a node N_U2, and a gate connected to the node RFSET. The transistor TR111 has a first end connected to a node BAD_U, a second end connected to the node N_U2, and a gate connected to a node RFRST.

The transistor TR112 has a first end connected to the node N_U2, a second end connected to a node PBUSBS, and a gate connected to a node N_U3. The transistor TR113 has a first end connected to the node PBUSBS, a second end grounded, and a gate connected to the node BB_SR_ENB.

The inverter INV15 has an input end connected to the node GOOD_U and an output end connected to the node BAD_U. That is, the inverter INV15 inverts the logic level of the node GOOD_U and outputs the inverted logic level to the node BAD_U. The inverter INV16 has an input end connected to the node BAD_U and an output end connected to the node GOOD_U. That is, the inverter INV16 inverts the logic level of the node BAD_U and outputs the inverted logic level to the node GOOD_U.

The transistor TR114 has a first end connected to the node GOODari_Un, a second end to be grounded, and a gate connected to the node N_U3.

The decoder PBD_U includes transistors TR120 and TR121, an inverter INV17, and a logic circuit AND2. The transistors TR120 and TR121 are, for example, P-type transistors.

The transistor TR120 includes a first end to which the voltage VDD is applied, a second end connected to the node GOODari_Un, and a gate connected to the node RDEC0. The transistor TR121 has a first end to which the voltage VDD is applied, a second end connected to the node GOODari_Un, and a gate connected to a node GOODari_U.

The inverter INV17 has an input end connected to the node GOODari_Un and an output end connected to the node GOODari_U. That is, the inverter INV17 inverts the logic level of the node GOODari_Un and outputs the inverted logic level to the node GOODari_U.

The logic circuit AND2 includes a first input terminal connected to the node GOODari_U, a second input terminal connected to the node RDEC, and an output terminal connected to the node RDEC2_U. That is, the logical circuit AND2 executes the logical AND operation of the logical level of the node GOODari_U and the logical level of the node RDEC, and outputs the execution result to the node RDEC2_U.

With the above configuration, whether the partial blocks PBLK_U0 to PBLK_U (n−1) are in the bad state or the good state is stored in each of the n partial bad block information storage circuits PBB_U0 to PBB_U (n−1). In a case where the partial block PBLK_U in the block BLK to be selected is in the bad state, the logical level of the node RDEC2_U is the “L” level. In a case where the partial block PBLK_U in the block BLK to be selected is in the good state, the logic level of the node RDEC2_U is at the “H” level.

### 4.2.2 Second Example

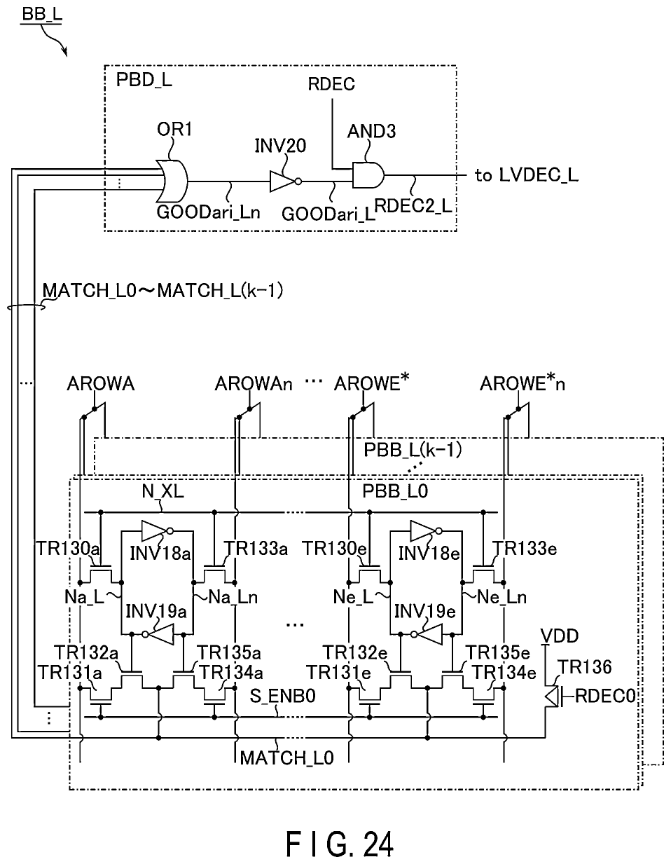

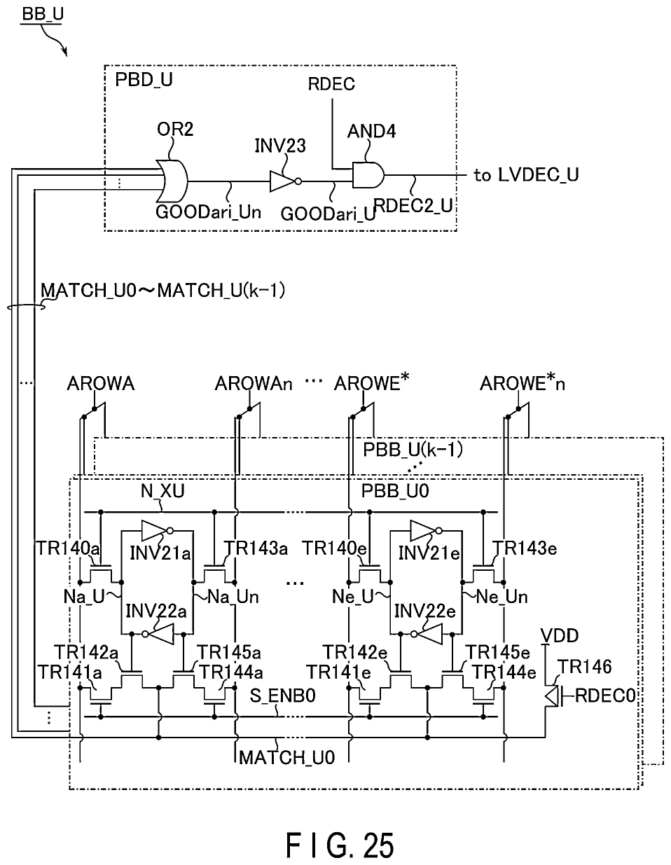

FIG. 24 is a circuit diagram illustrating a second example of the configuration of the first portion of the bad block information storage circuit according to the fourth embodiment. FIG. 25 is a circuit diagram illustrating a first example of the configuration of the second portion of the bad block information storage circuit according to the fourth embodiment.

First, the first portion BB_L of the bad block information storage circuit will be described.

As illustrated in FIG. 24, the first portion BB_L of the bad block information storage circuit may include a content addressable memory (CAM). Specifically, the first portion BB_L of the bad block information storage circuit includes a decoder PBD_L and a plurality of partial bad block information storage circuits PBB_L (PBB_L0, . . . , and PBB_L (k−1)). k is an integer of n or less, and is the maximum value of the number of partial blocks PBLK that can be managed to be in the bad state in the memory device 3. k is, for example, about 30% of the total number of partial blocks PBLK included in the memory device 3.

Each of the plurality of partial bad block information storage circuits PBB_L is connected in parallel to a node GOODari_Ln. Each of the plurality of partial bad block information storage circuits PBB_L0 to PBB_L (k−1) stores information indicating the block address BAd of the partial block PBLK_L in the bad state. Each of the plurality of partial bad block information storage circuits PBB_L has the same configuration. Hereinafter, as an example, a configuration of the partial bad block information storage circuit PBB_L0 will be described.

The partial bad block information storage circuit PBB_L0 includes a plurality of transistors TR130, TR131, TR132, TR133, TR134, and TR135, a plurality of inverters INV18 and INV19, and a transistor TR136. The plurality of transistors TR130 to TR135 includes, for example, a set of transistors TR130a to TR135a and a set of transistors . . . , TR130e to TR135e respectively corresponding to the nodes AROWA, . . . , and AROWE*. The plurality of transistors TR130 to TR135 is, for example, N-type transistors. The transistor TR136 is, for example, a P-type transistor.

The set of transistors TR130a to TR135a, . . . , and the set of TRs 130e to TR135e have the same configuration except that the nodes to be connected are AROWA to AROWE*, respectively. Hereinafter, as an example, a set of transistors TR130a to TR135a and a set of transistors TR130e to TR135e will be described.

The transistor TR130a has a first end connected to the node AROWA, a second end connected to a node Na_L, and a gate connected to a node N_XL. The transistor 131a has a first end connected to the node AROWA and a gate connected to a node S_ENB0. The transistor TR132a has a first end connected to a second end of the transistor TR131a, a second end connected to a node MATCH_L0, and a gate connected to the node Na_L.

The transistor TR133a has a first end connected to a node AROWAn, a second end connected to a node Na_Ln, and a gate connected to the node N_XL. The transistor 134a has a first end connected to the node AROWAn and a gate connected to the node S_ENB0. The transistor TR135a has a first end connected to a second end of a transistor TR134a, a second end connected to the node MATCH_L0, and a gate connected to the node Na_Ln.

The inverter INV18a has an input end connected to the node Na_L and an output end connected to the node Na_Ln. That is, the inverter INV18a inverts the logic level of the node Na_L and outputs the inverted logic level to the node Na_Ln. The inverter INV19a has an input end connected to the node Na_Ln and an output end connected to the node Na_L. That is, the inverter INV19a inverts the logic level of the node Na_Ln and outputs the inverted logic level to the node Na_L.

The transistor TR130e has a first end connected to the node AROWE*, a second end connected to the node Ne_L, and a gate connected to the node N_XL. The transistor 131e has a first end connected to the node AROWE* and a gate connected to the node S_ENB0. The transistor TR132e has a first end connected to a second end of the transistor TR131e, a second end connected to the node MATCH_L0, and a gate connected to the node Ne_L.

The transistor TR133e has a first end connected to a node AROWE*n, a second end connected to the node Ne_Ln, and a gate connected to the node N_XL. The transistor 134e has a first end connected to the node AROWE*n and a gate connected to the node S_ENB0. The transistor TR135e has a first end connected to a second end of the transistor TR134e, a second end connected to the node MATCH_L0, and a gate connected to the node Ne_Ln.

The inverter INV18e has an input terminal connected to the node Ne_L and an output terminal connected to the node Ne_Ln. That is, the inverter INV18e inverts the logic level of the node Ne_L and outputs the inverted logic level to the node Ne_Ln. The inverter INV19e has an input terminal connected to the node Ne_Ln and an output terminal connected to the node Ne_L. That is, the inverter INV19e inverts the logic level of the node Ne_Ln and outputs the inverted logic level to the node Ne_L.

The transistor TR136 has a first end to which the voltage VDD is applied, a second end connected to the node MATCH_L0, and a gate connected to the node RDEC0.

The k partial bad block information storage circuits PBB_L0 to PBB_L (k−1) having the above configuration are connected to the decoder PBD_L through the nodes MATCH_L0 to MATCH_L (k−1), respectively.

The decoder PBD_L includes an inverter INV20 and logic circuits OR1 and AND3.

The logic circuit OR1 has a first input terminal to a k-th input terminal connected to the nodes MATCH_L0 to MATCH_L (k−1), respectively, and an output terminal connected to the node GOODari_Ln. That is, in a case where the logic level of any one node of the nodes MATCH_L0 to MATCH_L (k−1) is the “H” level, the logic circuit OR1 sets the logic level of the node GOODari_Ln to the “H” level. In a case where the logic level of all of the nodes MATCH_L0 to MATCH_L (k−1) is the “L” level, the logic circuit OR1 sets the logic level of the node GOODari_Ln to the “L” level. That is, in a case where the address of the partial block PBLK_L to be selected matches the address stored in the partial bad block information storage circuit PBB_Lx, the logic level of the node MATCH_Lx becomes the “H” level (0≤x≤n).

The inverter INV20 has an input terminal connected to the node GOODari_Ln and an output terminal connected to the node GOODari_L. That is, the inverter INV20 inverts the logic level of the node GOODari_Ln and outputs the inverted logic level to the node GOODari_L.

The logic circuit AND3 has a first input terminal connected to the node GOODari_L, a second input terminal connected to the node RDEC, and an output terminal connected to the node RDEC2_L. That is, the logical circuit AND3 executes the logical AND operation of the logical level of the node GOODari_L and the logical level of the node RDEC, and outputs the execution result to the node RDEC2_L.

With the above configuration, information indicating the block address BAd corresponding to the partial block PBLK_L in the bad state is stored in each of the k partial bad block information storage circuits PBB_L0 to PBB_L (k−1). In a case where the partial block PBLK_L in the block BLK to be selected is in the bad state, the logical level of the node RDEC2_L is the “L” level. In a case where the partial block PBLK_L in the block BLK to be selected is in the good state, the logic level of the node RDEC2_L becomes the “H” level.

Next, the second portion BB_U of the bad block information storage circuit will be described.

As illustrated in FIG. 25, the second portion BB_U of the bad block information storage circuit may include a content addressable memory, similarly to the first portion BB_L. Specifically, the second portion BB_U of the bad block information storage circuit includes a decoder PBD_U and a plurality of partial bad block information storage circuits PBB_U (PBB_U0, . . . , and PBB_U (k−1)).

Each of the plurality of partial bad block information storage circuits PBB_U is connected in parallel to a node GOODari_Un. Each of the plurality of partial bad block information storage circuits PBB_U0 to PBB_U (k−1) stores information indicating the block address BAd of the partial block PBLK_U in the bad state. Each of the plurality of partial bad block information storage circuits PBB_U has an equivalent configuration. Hereinafter, as an example, a configuration of the partial bad block information storage circuit PBB_U0 will be described.

The partial bad block information storage circuit PBB_U0 includes a plurality of transistors TR140, TR141, TR142, TR143, TR144, and TR145, a plurality of inverters INV21 and INV22, and a transistor TR146. The plurality of transistors TR140˜145 include, for example, a set of transistors TR140a to TR145a and a set of . . . , TR140e to TR145e respectively corresponding to the nodes AROWA, . . . , and AROWE*. The plurality of transistors TR140˜145 are, for example, N-type transistors. The transistor TR146 is, for example, a P-type transistor.

The set of transistors TR140a to TR145a, . . . , and the set of TRs 140e to TR145e have the same configuration except that the nodes to be connected are AROWA to AROWE*, respectively. Hereinafter, as an example, a set of transistors TR140a to TR145a and a set of transistors TR140e to TR145e will be described.

The transistor TR140a has a first end connected to the node AROWA, a second end connected to a node Na_U, and a gate connected to a node N_XU. The transistor 141a has a first end connected to the node AROWA and a gate connected to the node S_ENB0. The transistor TR142a has a first end connected to a second end of the transistor TR141a, a second end connected to a node MATCH_U0, and a gate connected to the node Na_U.

The transistor TR143a has a first end connected to the node AROWAn, a second end connected to the node Na_Un, and a gate connected to the node N_XU. The transistor 144a has a first end connected to the node AROWAn and a gate connected to the node S_ENB0. The transistor TR145a has a first end connected to a second end of the transistor TR144a, a second end connected to the node MATCH_U0, and a gate connected to the node Na_Un.

The inverter INV21a has an input end connected to the node Na_U and an output end connected to the node Na_Un. That is, the inverter INV21a inverts the logic level of the node Na_U and outputs the inverted logic level to the node Na_Un. The inverter INV21a has an input end connected to the node Na_Un and an output end connected to the node Na_U. That is, the inverter INV21a inverts the logic level of the node Na_Un and outputs the inverted logic level to the node Na_U.

The transistor TR140e has a first end connected to the node AROWE*, a second end connected to the node Ne_U, and a gate connected to the node N_XU. The transistor 141e has a first end connected to the node AROWE* and a gate connected to the node S_ENB0. The transistor TR142e has a first end connected to a second end of the transistor TR141e, a second end connected to the node MATCH_U0, and a gate connected to the node Ne_U.

The transistor TR143e has a first end connected to the node AROWE*n, a second end connected to the node Ne_Un, and a gate connected to the node N_XU. The transistor 144e has a first end connected to the node AROWE*n and a gate connected to the node S_ENB0. The transistor TR145e has a first end connected to a second end of the transistor TR144e, a second end connected to the node MATCH_U0, and a gate connected to the node Ne_Un.

The inverter INV21e has an input end connected to the node Ne_U and an output end connected to the node Ne_Un. That is, the inverter INV21e inverts the logic level of the node Ne_U and outputs the inverted logic level to the node Ne_Un. The inverter INV22e has an input terminal connected to the node Ne_Un and an output terminal connected to the node Ne_U. That is, the inverter INV22e inverts the logic level of the node Ne_Un and outputs the inverted logic level to the node Ne_U.

The transistor TR146 has a first end to which the voltage VDD is applied, a second end connected to the node MATCH_U0, and a gate connected to the node RDEC0.

The k partial bad block information storage circuits PBB_U0 to PBB_U (k−1) having the above configuration are connected to the decoder PBD_U through the nodes MATCH_U0 to MATCH_U (k−1), respectively.

The decoder PBD_U includes an inverter INV23 and logic circuits OR2 and AND4.

The logic circuit OR2 has a first input terminal to a k-th input terminal connected to the nodes MATCH_U0 to MATCH_U (k−1), respectively, and an output terminal connected to the node GOODari_Un. That is, in a case where the logic level of any one node of the nodes MATCH_U0 to MATCH_U (k−1) is the “H” level, the logic circuit OR2 sets the logic level of the node GOODari_Un to the “H” level. In a case where the logic level of all of the nodes MATCH_U0 to MATCH_U (k−1) is the “L” level, the logic circuit OR2 sets the logic level of the node GOODari_Un to the “L” level. That is, in a case where the address of the partial block PBLK_U to be selected matches the address stored in the partial bad block information storage circuit PBB_Ux, the logic level of a node MATCH_Ux becomes the “H” level (0≤x≤n).

The inverter INV23 has an input end connected to the node GOODari_Un and an output end connected to the node GOODari_U. That is, the inverter INV23 inverts the logic level of the node GOODari_Un and outputs the inverted logic level to the node GOODari_U.

The logic circuit AND4 includes a first input terminal connected to the node GOODari_U, a second input terminal connected to the node RDEC, and an output terminal connected to the node RDEC2_U. That is, the logic circuit AND4 executes an AND operation of the logic level of the node GOODari_U and the logic level of the node RDEC, and outputs an execution result to the node RDEC2_U.

With the above configuration, information indicating the block address BAd corresponding to the partial block PBLK_U in the bad state is stored in each of the k partial bad block information storage circuits PBB_U0 to PBB_U (k−1). In a case where the partial block PBLK_U in the block BLK to be selected is in the bad state, the logical level of the node RDEC2_U is the “L” level. In a case where the partial block PBLK_U in the block BLK to be selected is in the good state, the logic level of the node RDEC2_U is at the “H” level.

### 4.2 Effects According to the Fourth Embodiment

According to the fourth embodiment, the block decoders BD_U and BD_L do not include the partial bad block latches PBBL_U and PBBL_L, respectively. The memory device 3 includes a first portion BB_L and a second portion BB_U of the bad block information storage circuit instead of the partial bad block latches PBBL_U and PBBL_L. The first portion BB_L and the second portion BB_U of the bad block information storage circuit are provided not in the transfer region XR but in the peripheral circuit region PERI. Also, in this case, the row decoder module 15 can independently control the partial block PBLK_U and the partial block PBLK_L in the same block BLK. Therefore, an increase in the circuit area of the memory cell array 10 can be suppressed, and the use efficiency can be improved.

### 5. Modifications and the Like

Note that the first to fourth embodiments are not limited to the above-described examples, and various modifications can be applied.

In the first to fourth embodiments described above, in a case where there is the block BLK including the partial block PBLK in the good state and the partial block PBLK in the bad state, a case where the partial block PBLK in the good state of the block BLK is selected in the operation of applying the predetermined voltage to the word line WL such as the write operation and the read operation has been described, but the present invention is not limited thereto. For example, in a case where there are two or more blocks BLK including the partial block PBLK in the good state and the partial block PBLK in the bad state, the memory device 3 may select the partial blocks PBLK in the good state of each of the two different blocks BLK as one block BLK. As a result, the management load of the partial block PBLK by the memory controller 2 can be reduced.

In the second embodiment described above, the case where the number and type of the word lines WL that can independently control the partial blocks PBLK_U and PBLK_L are common to all the blocks BLK has been described, but the present invention is not limited thereto. For example, the number and type of the word lines WL that can independently control the partial blocks PBLK_U and PBLK_L may be different for each block BLK. More specifically, for example, in the block BLK located at the end portion of the memory cell array 10, the number of word lines WL that can independently control the partial blocks PBLK_U and PBLK_L may be set to be large. As a result, it is possible to independently control more word lines WL for the block BLK in which a failure is likely to occur due to manufacturing characteristic variations and the like. In addition, the number of word lines WL to be independently controlled is reduced for the block BLK in which failure is relatively less likely to occur, so that it is possible to suppress complication of the circuit.

In addition, in the third embodiment described above, the case where the row decoder set EOC_RD is configured to control the two blocks BLK_e and BLK_o has been described, but the present invention is not limited thereto. The row decoder set EOC_RD may be configured to control three or more blocks BLK. In this case, each of the block decoder sets EOC_BD_U and EOC_BD_L includes partial bad block latches PBBL corresponding to the number of blocks BLK to be controlled. That is, the row decoder set EOC_RD includes two partial bad block latches PBBL_U and PBBL_L for each block BLK. As a result, the partial blocks PBLK_U and PBLK_L can be independently controlled for each block BLK.

While certain embodiments have been described, these embodiments have been presented by way of example only, and are not intended to limit the scope of the invention. Indeed, the embodiments described herein may be embodied in a variety of other forms; furthermore, various omissions, substitutions and changes in the form of the embodiments described herein may be made without departing from the spirit of the inventions. The embodiments and modifications are included in the scope and spirit of the invention and are included in the scope of the claimed inventions and their equivalents.

What is claimed is:

1. A memory device, comprising:
a first chip including a first memory cell array;
a second chip including a second memory cell array and in contact with the first chip; and
a third chip including a control circuit and in contact with the second chip,
wherein
the first memory cell array includes a first transistor and a second transistor coupled in series,
the second memory cell array includes a third transistor and a fourth transistor coupled in series, and
the control circuit includes:
a fifth transistor having a first end electrically coupled to a gate of the first transistor;
a sixth transistor having a first end electrically coupled to a gate of the third transistor;
a seventh transistor having a first end electrically coupled to a gate of the second transistor and a gate of the fourth transistor;
a first decoder configured to switch a state of the fifth transistor; and
a second decoder configured to switch a state of the sixth transistor independently of the state of the fifth transistor.

2. The memory device according to claim 1, wherein
the control circuit further includes a third decoder, and
the third decoder is configured to:
turn on a state of the seventh transistor in a case where the state of the fifth transistor is turned on or in a case where the state of the sixth transistor is turned on; and
turn off the state of the seventh transistor in a case where the state of the fifth transistor is turned off and the state of the sixth transistor is turned off.

3. The memory device according to claim 2, wherein
the first decoder is configured to supply a first signal to a gate of the fifth transistor based on first information, and
the second decoder is configured to supply a second signal to a gate of the sixth transistor based on second information, and
the third decoder is configured to supply a third signal to a gate of the seventh transistor based on the first information and the second information.

4. The memory device according to claim 3, wherein
the first decoder includes a first latch configured to store the first information, and
the second decoder includes a second latch configured to store the second information.

5. The memory device according to claim 3, wherein
the first information indicates whether the first transistor and the second transistor function or not, and
the second information indicates whether the third transistor and the fourth transistor function or not.

6. The memory device according to claim 2, wherein
the first decoder is coupled to a gate of the fifth transistor through a first wiring,
the second decoder is coupled to a gate of the sixth transistor through a second wiring, and
the third decoder is coupled to a gate of the seventh transistor through a third wiring.

7. The memory device according to claim 2, wherein
the first memory cell array further includes an eighth transistor and a ninth transistor coupled in series without being coupled in series to the first transistor and the second transistor, and
the second memory cell array further includes a tenth transistor and an eleventh transistor coupled in series without being coupled in series with the third transistor and the fourth transistor, and
the control circuit further includes:
a twelfth transistor having a first end electrically coupled to a gate of the eighth transistor;
a thirteenth transistor having a first end electrically coupled to a gate of the tenth transistor; and
an fourteenth transistor having a first end electrically coupled to a gate of the ninth transistor and a gate of the eleventh transistor,
the first decoder is configured to switch the state of the fifth transistor and a state of the twelfth transistor, and
the second decoder is configured to switch the state of the sixth transistor and a state of the thirteenth transistor independently of the state of the fifth transistor and the state of the twelfth transistor.

8. The memory device according to claim 7, wherein
the first decoder is configured to:
supply a first signal to a gate of the fifth transistor and a gate of the twelfth transistor based on first information; and
supply a fourth signal to the gate of the fifth transistor and the gate of the twelfth transistor based on third information,
the second decoder is configured to:
supply a second signal to a gate of the sixth transistor and a gate of the thirteenth transistor based on second information; and
supply a fifth signal to the gate of the sixth transistor and the gate of the thirteenth transistor based on the fourth information, and
the third decoder is configured to:
supply a third signal to a gate of the seventh transistor and a gate of the fourteenth transistor based on the first information and the second information; and
supply a sixth signal to the gate of the seventh transistor and the fourteenth transistor based on the third information and the fourth information.

9. The memory device according to claim 8, wherein
the first decoder includes:
a first latch configured to store the first information; and
a third latch configured to store the third information, and
the second decoder includes:
a second latch configured to store the second information; and
a fourth latch configured to store the fourth information.

10. The memory device according to claim 8, wherein
the first information indicates whether the first transistor and the second transistor function or not,
the second information indicates whether the third transistor and the fourth transistor function or not,
the third information indicates whether the eighth transistor and the ninth transistor function or not, and
the fourth information indicates whether the tenth transistor and the eleventh transistor function or not.

11. The memory device according to claim 1, wherein
the first transistor is a select transistor, and
the second transistor is a memory cell transistor.

12. The memory device according to claim 1, wherein
the first transistor and the second transistor are memory cell transistors.

13. The memory device according to claim 11, wherein
the first chip, the second chip, and the third chip are arranged in a first direction,
the first memory cell array includes:
a first conductor layer and a second conductor layer, each of the first conductor layer and the second conductor layer extending in a plane intersecting with the first direction and provided apart from each other in the first direction; and
a first member extending in the first direction and having a first portion intersecting with the first conductor layer to function as the first transistor and a second portion intersecting with the second conductor layer to function as the second transistor, and
the first portion is located at an end portion of the first member with respect to the second portion in the first direction.

14. The memory device according to claim 12, wherein
the first chip, the second chip, and the third chip are arranged in a first direction,
the first memory cell array includes:
a first conductor layer and a second conductor layer, each of the first conductor layer and the second conductor layer extending in a plane intersecting with the first direction and provided apart from each other in the first direction; and
a first member extending in the first direction and having a first portion intersecting with the first conductor layer to function as the first transistor and a second portion intersecting with the second conductor layer to function as the second transistor, and
the first portion is located at an end portion of the first member with respect to the second portion in the first direction.

15. The memory device according to claim 11, wherein
the first chip, the second chip, and the third chip are arranged in a first direction,
the first memory cell array includes:
a first conductor layer and a second conductor layer, each of the first conductor layer and the second conductor layer extending in a plane intersecting with the first direction and provided apart from each other in the first direction; and
a first member extending in the first direction and having a first portion intersecting with the first conductor layer to function as the first transistor and a second portion intersecting with the second conductor layer to function as the second transistor,
the first member includes:
a first sub-member including the first portion; and
a second sub-member in contact with the first sub-member in the first direction,
a side surface of the first sub-member is shifted from an extension of a side surface of the second sub-member, and
the first portion is located at an end of the first sub-member with respect to the second portion in the first direction.

16. The memory device according to claim 12, wherein
the first chip, the second chip, and the third chip are arranged in a first direction,
the first memory cell array includes:
a first conductor layer and a second conductor layer, each of the first conductor layer and the second conductor layer extending in a plane intersecting with the first direction and provided apart from each other in the first direction; and
a first member extending in the first direction and having a first portion intersecting with the first conductor layer to function as the first transistor and a second portion intersecting with the second conductor layer to function as the second transistor,
the first member includes:
a first sub-member including the first portion; and
a second sub-member in contact with the first sub-member in the first direction,
a side surface of the first sub-member is shifted from an extension of a side surface of the second sub-member, and
the first portion is located at an end of the first sub-member with respect to the second portion in the first direction.

17. A memory device, comprising:
a first chip including a first memory cell array;
a second chip including a second memory cell array and in contact with the first chip; and
a third chip including a control circuit and in contact with the second chip,
wherein
the first memory cell array includes a first transistor and a second transistor coupled in series,
the second memory cell array includes a third transistor and a fourth transistor coupled in series, and
the control circuit includes:
a fifth transistor having a first end electrically coupled to a gate of the first transistor;
a sixth transistor having a first end electrically coupled to a gate of the third transistor;
a seventh transistor having a first end electrically coupled to a gate of the second transistor and a gate of the fourth transistor; and
a decoder configured to switch a state of the fifth transistor and a state of the sixth transistor independently.

18. The memory device according to claim 17, wherein
each of the first memory cell array and the second memory cell array includes a plurality of partial blocks, and
a first partial block among the plurality of partial blocks included in the first memory cell array includes the first transistor and the second transistor,
a second partial block among the plurality of partial blocks included in the second memory cell array includes the third transistor and the fourth transistor,
a set including the first partial block and the second partial block is a unit of erasing data, and
the decoder corresponds to the set including the first partial block and the second partial block.

19. The memory device according to claim 18, wherein
the decoder includes:
a first decoder corresponding to the first partial block and configured to switch the state of the fifth transistor; and
a second decoder corresponding to the second partial block and configured to switch the state of the sixth transistor independently of the state of the fifth transistor.
